(19) United States
(12) Patent Application Publication
(10) Pub. No.: US 2022/0213328 A1
(43) Pub. Date: Jul. 7, 2022

(54) COMPOSITION, FILM, STRUCTURAL BODY, COLOR FILTER, SOLID-STATE IMAGING ELEMENT, AND IMAGE DISPLAY DEVICE

(71) Applicant: FUJIFILM Corporation, Tokyo (JP)

(72) Inventors: Shoichi NAKAMURA, Shizuoka (JP); Masahiro MORI, Shizuoka (JP)

(73) Assignee: FUJIFILM Corporation, Tokyo (JP)

(21) Appl. No.: 17/672,709

(22) Filed: Feb. 16, 2022

Related U.S. Application Data
(63) Continuation of application No. PCT/JP2020/032799, filed on Aug. 31, 2020.

(30) Foreign Application Priority Data
Sep. 6, 2019 (JP) 2019-162617

(51) Int. Cl. C09C 1/30; C09C 3/12; G02B 5/20

(52) U.S. Cl. CPC C09C 1/3081; C09C 3/12; C01P 2004/50; C01P 2004/32; G02B 5/201

(57) ABSTRACT

Provided are a composition including at least one selected from silica particles in a shape in which a plurality of spherical silicas are connected in a bead shape or silica particles in a shape in which a plurality of spherical silicas are connected in a plane, and a solvent, in which at least a part of hydroxy groups on a surface of the silica particles is treated with a hydrophobizing treatment agent which reacts with the hydroxy group; a film formed of the composition; a structural body; a color filter; a solid-state imaging element; and an image display device.

### CROSS-REFERENCE TO RELATED APPLICATIONS

This application is a Continuation of PCT International Application No. PCT/JP2020/032799 filed on Aug. 31, 2020, which claims priority under 35 U.S.C § 119(a) to Japanese Patent Application No. 2019-162617 filed on Sep. 6, 2019. Each of the above application(s) is hereby expressly incorporated by reference, in its entirety, into the present application.

### BACKGROUND OF THE INVENTION

### 1. Field of the Invention

The present invention relates to a composition including silica particles. The present invention further relates to a film formed of the composition including silica particles, a structural body, a color filter, a solid-state imaging element, and an image display device.

### 2. Description of the Related Art

An optically functional layer such as a low refractive index film is applied to, for example, a surface of a transparent base material in order to prevent reflection of incident light. Application fields of the optically functional layer are wide, and the optically functional layer is applied to products in various fields such as an optical instrument, a building material, an observation instrument, and a windowpane. As a material thereof, various materials, both organic and inorganic, are used and targeted for development. Among these, in recent years, development of materials applied to an optical instrument has been promoted. Specifically, in a display panel, an optical lens, an image sensor, and the like, a search for materials having physical properties and workability, which are suitable for the products, has been promoted.

For example, an optically functional layer applied to a precision optical instrument such as an image sensor is required to have fine and accurate workability. Therefore, in the related art, a vapor phase method such as a vacuum evaporation method and a sputtering method, which is suitable for fine process, has been adopted. As a material, for example, a single-layer film consisting of MgF₂, cryolite, or the like has been put into practical use. In addition, attempts have also been made to apply a metal oxide such as SiO₂, TiO₂, and ZrO₂.

On the other hand, in the vapor phase method such as a vacuum evaporation method and a sputtering method, since processing equipment and the like are expensive, manufacturing cost may be high. Correspondingly, in recent years, it has been studied to manufacture the optically functional layer such as a low refractive index film using a composition including silica particles.

JP2014-034488A discloses an invention relating to silica having a hollow structure. WO2000-015552A discloses an invention relating to beaded silica.

### SUMMARY OF THE INVENTION

Further improvement in moisture resistance has been desired for a film formed of a composition including silica.

Therefore, an object of the present invention is to provide a composition capable of forming a film having excellent moisture resistance. Another object of the present invention is to provide a film formed of the composition, a structural body, a color filter, a solid-state imaging element, and an image display device.

According to the studies conducted by the present inventors, it has been found that the above-described object can be achieved by using a composition described below, thereby leading to the completion of the present invention. Therefore, the present invention provides the following.

<1> A composition comprising:
at least one selected from silica particles in a shape in which a plurality of spherical silicas are connected in a bead shape or silica particles in a shape in which a plurality of spherical silicas are connected in a plane; and
a solvent,
in which at least a part of hydroxy groups on a surface of the silica particles is treated with a hydrophobizing treatment agent which reacts with the hydroxy group.

<2> The composition according to <1>,
in which the hydrophobizing treatment agent is an organosilicon compound.

<3> The composition according to <1>,
in which the hydrophobizing treatment agent is an organosilane compound.

<4> The composition according to <1>,
in which the hydrophobizing treatment agent is at least one selected from an alkylsilane compound, an alkoxysilane compound, a halogenated silane compound, an aminosilane compound, or a silazane compound.

<5> The composition according to any one of <1> to <4>,
in which the solvent includes an alcohol-based solvent.

<6> The composition according to any one of <1> to <5>,
in which the composition is a composition for forming a member adjacent to a colored layer of a color filter which has the colored layer.

<7> The composition according to any one of <1> to <6>,
in which the composition is a composition for forming a partition wall.

<8> The composition according to <7>,
in which the composition is a composition for forming a partition wall of a structural body which has a support, the partition wall provided on the support, and a colored layer provided in a region partitioned by the partition wall.

<9> A film obtained from the composition according to any one of <1> to <8>.

<10> A structural body comprising:
a support;
a partition wall obtained from the composition according to any one of <1> to <8>,
which is provided on the support; and
a colored layer provided in a region partitioned by the partition wall.

<11> A color filter comprising:
the film according to <9>.

<12> A solid-state imaging element comprising:
the film according to <9>.

<13> An image display device comprising:
the film according to <9>.

According to the present invention, it is possible to provide a composition capable of forming a film having excellent moisture resistance. In addition, it is possible to provide a film formed of the composition, a structural body, a color filter, a solid-state imaging element, and an image display device.

### BRIEF DESCRIPTION OF THE DRAWINGS

FIG. 1 is an enlarged view schematically showing silica particles having a shape in which a plurality of spherical silicas are connected in a bead shape.

FIG. 2 is a side-sectional view showing an embodiment of a structural body according to the present invention.

FIG. 3 is a plan view of the structural body as viewed from directly above a support.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, a weight-average molecular weight and a number-average molecular weight adopt values in terms of polystyrene, measured by gel permeation chromatography (GPC). As a measuring device and measuring conditions, the following condition 1 is basically applied, and the following condition 2 is allowed depending on the solubility of the sample and the like. However, depending on polymer species, an appropriate carrier (eluent) and a column suitable for the carrier may be selected and used as appropriate. For other matters, JIS K7252-1 to 4:2008 can be referred to.
(Condition 1)
Column: columns formed by connection of TOSOH TSKgel Super HZM-H, TOSOH TSKgel Super HZ4000, and TOSOH TSKgel Super HZ2000
Carrier: tetrahydrofuran
Measurement temperature: 40° C.
Carrier flow rate: 1.0 ml/min
Sample concentration: 0.1 mass %
Detector: refractive index (RI) detector
Injection amount: 0.1 ml
(Condition 2)
Column: columns formed by connection of two TOSOH TSKgel Super AWM-H's
Carrier: 10 mM LiBr/N-methylpyrrolidone
Measurement temperature: 40° C.
Carrier flow rate: 1.0 ml/min
Sample concentration: 0.1 mass %
Detector: refractive index (RI) detector
Injection amount: 0.1 ml

<Composition>

A composition according to an embodiment of the present invention includes at least one selected from silica particles in a shape in which a plurality of spherical silicas are connected in a bead shape or silica particles in a shape in which a plurality of spherical silicas are connected in a plane, and a solvent, in which at least a part of hydroxy groups on a surface of the silica particles is treated with a hydrophobizing treatment agent which reacts with the hydroxy group. Hereinafter, the silica particles in a shape in which a plurality of spherical silicas are connected in a bead shape and the silica particles in a shape in which a plurality of spherical silicas are connected in a plane are collectively referred to as beaded silica.

With the composition according to the embodiment of the present invention, it is possible to form a film having excellent moisture resistance, and it is possible to suppress a change in refractive index even in a case where the obtained film is exposed to a high humidity environment. The reason for obtaining such an effect is assumed as follows. In a film formed by using a composition including beaded silica, a large number of relatively small voids in the film are likely to be formed in the film, and a low refractive index can be achieved by forming a large number of such voids. On the other hand, the present inventor has found that the formation of such voids in the film tends to allow other substances such as water to be easily taken in. In the present invention, by using, as the beaded silica, silica particles (hereinafter, also referred to as silica particles A) in which at least a part of hydroxy groups on a surface of the silica particles is treated with a hydrophobizing treatment agent, it is possible to effectively suppress uptake of water and the like into the voids formed in the film, and as a result, it is assumed that it is possible to form a film having excellent moisture resistance, in which refractive index does not easily fluctuate even in a case of being exposed to a high humidity environment.

In addition, the composition according to the embodiment of the present invention has excellent temporal stability, and further, by using the composition according to the embodiment of the present invention, it is also possible to form a film in which generation of defects such as irregularities, derived from aggregates of the silica particles, is suppressed. Since the at least a part of hydroxy groups on the surface of the silica particles is treated with a hydrophobizing treatment agent, it is assumed that aggregation of the silica particles can be suppressed.

In addition, even in a case where a structural body having another film (for example, a colored layer or the like) adjacent to the film formed of the composition according to the embodiment of the present invention is exposed to a high humidity environment, it is possible to suppress generation of voids and the like between the film formed of the composition according to the embodiment of the present invention and the another film, variation in spectral characteristics of the another film, and the like.

The viscosity of the composition according to the embodiment of the present invention at 25° C. is preferably 3.6 mPa·s or less, more preferably 3.4 mPa·s or less, and still more preferably 3.2 mPa·s or less. In addition, the lower limit is preferably 1.0 mPa·s or more, more preferably 1.4 mPa·s or more, and still more preferably 1.8 mPa·s or more. In a case where the viscosity of the composition is within the above-described range, application properties of the composition are enhanced, and it is easy to form a film in which the generation of defects is further suppressed.

The concentration of solid contents of the composition according to the embodiment of the present invention is preferably 5 mass % or more, more preferably 7 mass % or more, and still more preferably 8 mass % or more. The upper limit is preferably 15 mass % or less, more preferably 12 mass % or less, and still more preferably 10 mass % or less. In a case where the concentration of solid contents of the composition according to the embodiment of the present invention is within the above-described range, it is easy to form a film having a low refractive index and more suppressed generation of defects.

From the reason that it is easy to stabilize dispersion of the silica particles in the composition and suppress the generation of aggregates, the absolute value of the zeta potential of the composition according to the embodiment of the present invention is preferably 25 mV or more, more preferably 29 mV or more, still more preferably 33 mV or more, and even more preferably 37 mV or more. The upper limit of the absolute value of the zeta potential is preferably 90 mV or less, more preferably 80 mV or less, and still more preferably 70 mV or less. In addition, from the reason that it is easy to stabilize dispersion of the silica particles A in the composition, the zeta potential of the present invention is preferably −70 to −25 mV. The lower limit is preferably −60 mV or more, more preferably −50 mV or more, and still more preferably −45 mV or more. The upper limit is preferably −28 mV or less, more preferably −31 mV or less, and still more preferably −34 mV or less. In a case where the potential of an electrically neutral solvent portion which is sufficiently spaced from the particles in a fine particle dispersion liquid is zero, the zeta potential refers to a potential on an internal plane (slipping plane) of an electric double layer that moves together with particles among potentials developed by surface charge of the particles and the electric double layer induced on the vicinity of the surface. In addition, in the present specification, the zeta potential of the composition is a value measured by electrophoresis. Specifically, the electrophoretic mobility of fine particles is measured using a zeta potential measuring device (Zetasizer Nano, manufactured by Malvern Panalitical Ltd.), and the zeta potential is obtained from the Debye-Huckel equation. As measurement conditions, a universal dip cell is used, a voltage at which particles appropriately electrophoretically migrate even after application of a voltage of 40 V or 60 V is selected, and an attenuator and an analysis model are set to an automatic mode, the measurement is repeated 20 times, and the average value thereof is obtained as the zeta potential of a sample. The sample is used as it is without performing a pre-treatment such as dilution thereon.

The surface tension of the composition according to the embodiment of the present invention at 25° C. is preferably 27.0 mN/m or less, more preferably 26.0 mN/m or less, still more preferably 25.5 mN/m or less, and even more preferably 25.0 mN/m or less. The lower limit is preferably 20.0 mN/m or more, more preferably 21.0 mN/m or more, and still more preferably 22.0 mN/m or more.

In a case where the composition according to the embodiment of the present invention is applied to a glass substrate and heated at 200° C. for 5 minutes to form a film having a thickness of 0.5 μm, from the viewpoint of stability of the composition, the contact angle of the film with water at 25° C. is preferably 20° or more, more preferably 25° or more, and still more preferably 30°. From the viewpoint of application properties of the composition, the upper limit is preferably 90° or less, more preferably 85° or less, and still more preferably 80° or less. The contact angle is a value measured using a contact angle meter (DM-701, manufactured by Kyowa Interface Science Co., Ltd.).

In a case where the composition according to the embodiment of the present invention is applied to a silicon wafer and heated at 200° C. for 5 minutes to form a film having a thickness of 0.3 μm, the refractive index of the film with light having a wavelength of 633 nm is preferably 1.400 or less, more preferably 1.350 or less, still more preferably 1.300 or less, and even more preferably 1.270 or less. The lower limit is not particularly limited, but can be 1.150 or more. The above-described refractive index is a value measured using an ellipsometer (VUV-vase, manufactured by J. A. Woollam). The measurement temperature is 25° C.

Hereinafter, respective components of the composition according to the embodiment of the present invention will be described.

<<Silica Particles (Silica Particles A)>>

The composition according to the embodiment of the present invention includes silica particles (silica particles A) which are at least one silica particle selected from silica particles in a shape in which a plurality of spherical silicas are connected in a bead shape and silica particles in a shape in which a plurality of spherical silicas are connected in a plane, and in which at least a part of hydroxy groups on a surface of the silica particles is treated with a hydrophobizing treatment agent which reacts with the hydroxy group. That is, the above-described silica particles A includes at least one selected from silica particles having a shape that a plurality of spherical silicas in which at least a part of hydroxy groups on the surface is treated with a hydrophobizing treatment agent are connected in a bead shape, or silica particles having a shape that a plurality of spherical silicas in which at least a part of hydroxy groups on the surface is treated with a hydrophobizing treatment agent are connected in a plane.

Hereinafter, the silica particles in a shape in which a plurality of spherical silicas are connected in a bead shape and the silica particles in a shape in which a plurality of spherical silicas are connected in a plane are collectively referred to as beaded silica. The silica particles in a shape in which a plurality of spherical silicas are connected in a bead shape may have a shape in which a plurality of spherical silicas are connected in a plane.

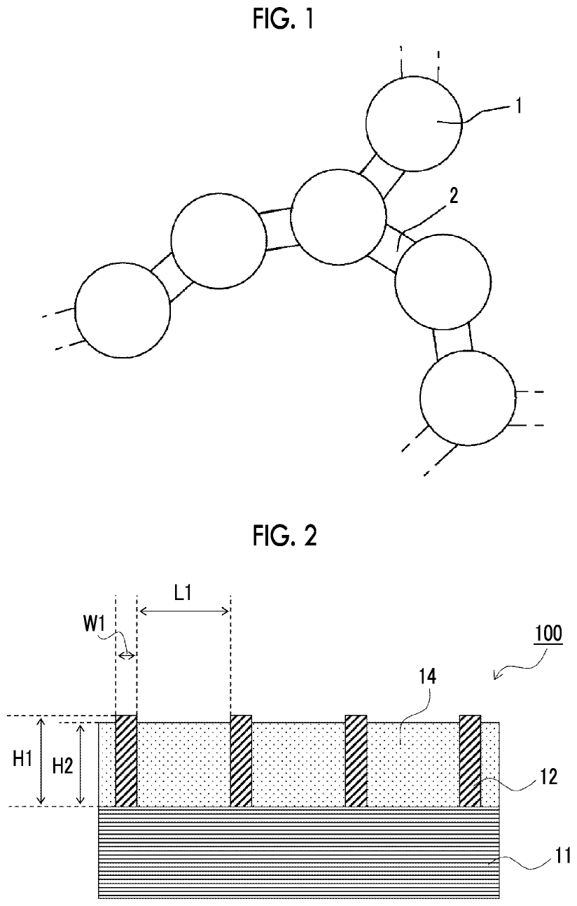

In the present specification, the “spherical” in the “spherical silica” means that the particle may be substantially spherical and may be deformed within a range in which the effect of the present invention is exhibited. For example, the “spherical” is meant to include a shape having roughness on the surface, and a flat surface having a long axis in a predetermined direction. In addition, the “a plurality of spherical silicas are connected in a bead shape” means a structure in which a plurality of spherical silicas are connected to each other in a linear and/or branched form. Examples thereof include a structure in which a plurality of spherical silicas 1 are connected by a connection portion 2 having a smaller outer diameter, as shown in FIG. 1. In addition, in the present invention, the structure in which “a plurality of spherical silicas are connected in a bead shape” includes not only a ring-shaped structure, but also a chain-shaped structure with ends. In addition, the “a plurality of spherical silicas are connected in a plane” means a structure in which a plurality of spherical silicas are connected to each other on substantially the same plane. The “substantially the same plane” means not only a case where the plurality of spherical silicas have the same plane, but also a case where the plurality of spherical silicas may be vertically displaced from the same plane. For example, the plurality of spherical silicas may be displaced up and down within a range of 50% or less of a particle diameter of the spherical silica.

In the beaded silica, a ratio D₁/D₂ of an average particle diameter D₁ measured by a dynamic light scattering method and an average particle diameter D₂ obtained by the following expression (1) is preferably 3 or more. The upper limit of D₁/D₂ is not particularly limited, but is preferably 1000 or less, more preferably 800 or less, and still more preferably 500 or less. By setting D₁/D₂ within such a range, good optical characteristics can be exhibited. The value of D₁/D₂ in the beaded silica is also an indicator of a degree of connection of the spherical silica.

D₂=2720/S (1)

In the expression, D₂ is an average particle diameter of the beaded silica, in units of nm, and S is a specific surface area of the beaded silica measured by a nitrogen adsorption method, in units of m²/g.

The above-described average particle diameter D₂ of the beaded silica can be regarded as an average particle diameter close to a diameter of primary particles of the spherical silica. The average particle diameter D₂ is preferably 1 nm or more, more preferably 3 nm or more, still more preferably 5 nm or more, and particularly preferably 7 nm or more. The upper limit is preferably 100 nm or less, more preferably 80 nm or less, still more preferably 70 nm or less, even more preferably 60 nm or less, and particularly preferably 50 nm or less.

The average particle diameter D₂ can be replaced by a circle-equivalent diameter (D0) in a projection image of the spherical portion measured by a transmission electron microscope (TEM). Unless otherwise specified, the average particle diameter based on the circle-equivalent diameter is evaluated by the number average of 50 or more particles.

The above-described average particle diameter D₁ of the beaded silica can be regarded as a number average particle diameter of secondary particles in which a plurality of spherical silicas are collected. Therefore, a relationship of D₁>D₂ is usually satisfied. The average particle diameter D₁ is preferably 5 nm or more, more preferably 7 nm or more, and particularly preferably 10 nm or more. The upper limit is preferably 100 nm or less, more preferably 70 nm or less, still more preferably 50 nm or less, and particularly preferably 45 nm or less.

Unless otherwise specified, the above-described average particle diameter D₁ of the beaded silica is measured using a dynamic light scattering type particle size distribution measuring device (Microtrac UPA-EX150, manufactured by Nikkiso Co., Ltd.). The procedure is as follows. A dispersion liquid of the beaded silica is divided into 20 ml sample bottle, and diluted with propylene glycol monomethyl ether so that the concentration of solid contents is 0.2 mass %. The diluted sample solution is irradiated with 40 kHz ultrasonic waves for 1 minute, and immediately after that, the sample solution is used for test. Data is captured 10 times using a 2 ml quartz cell for measurement at a temperature of 25° C., and the obtained “number average” is regarded as the average particle diameter. For other detailed conditions and the like, the description of “Particle size analysis—Dynamic light scattering method” in JIS Z8828:2013 can be referred to as necessary. Five samples are produced for each level and the average value thereof is adopted.

As the beaded silica, it is preferable that a plurality of spherical silicas having an average particle diameter of 1 to 80 nm are connected through a connecting material. The upper limit of the average particle diameter of the spherical silica is preferably 70 nm or less, more preferably 60 nm or less, and still more preferably 50 nm or less. In addition, the lower limit of the average particle diameter of the spherical silica is preferably 3 nm or more, more preferably 5 nm or more, and still more preferably 7 nm or more. In the present invention, as the value of the average particle diameter of the spherical silica, a value of an average particle diameter obtained from the circle-equivalent diameter in the projection image of the spherical portion measured by a transmission electron microscope (TEM) is used.

Examples of the connecting material for connecting the spherical silicas include metal oxide-containing silica. Examples of the metal oxide include an oxide of metal selected from Ca, Mg, Sr, Ba, Zn, Sn, Pb, Ni, Co, Fe, Al, In, Y, and Ti. Examples of the metal oxide-containing silica include a reaction product and a mixture of these metal oxides and silica (SiO₂). With regard to the connecting material, reference can be made to the description in WO2000/015552A, the content of which is incorporated herein by reference.

The number of connected spherical silicas in the beaded silica is preferably 3 or more and more preferably 5 or more. The upper limit is preferably 1000 or less, more preferably 800 or less, and still more preferably 500 or less. The number of connected spherical silicas can be measured by TEM.

Examples of a commercially available product of a sol (particle solution) of the beaded silica include SNOWTEX series and ORGANOSILICASOL series (methanol dispersion liquid, isopropyl alcohol dispersion liquid, ethylene glycol dispersion liquid, methyl ethyl ketone dispersion liquid, and the like; product numbers: IPA-ST-UP, MEK-ST-UP, and the like) manufactured by Nissan Chemical Corporation.

In the silica particles A, it is preferable that 1% to 80% of hydroxy groups on the surface of the silica particles are treated with a hydrophobizing treatment agent, it is more preferable that 3% to 50% thereof are treated with a hydrophobizing treatment agent, and it is still more preferable that 5% to 30% thereof are treated with a hydrophobizing treatment agent. A treatment rate of the hydroxy groups on the surface of the silica particles with the hydrophobizing treatment agent can be calculated by observing ²⁹Si signal by a solid-state nuclear magnetic resonance (NMR) method.

As the hydrophobizing treatment agent, a compound having a structure which reacts with the hydroxy group on the surface of the silica particles (preferably, a structure which reacts with the hydroxy group on the surface of the silica particles by coupling) so as to improve hydrophobicity of the silica particles is used. The hydrophobizing treatment agent is preferably an organic compound. Specific examples of the hydrophobizing treatment agent include an organosilicon compound, an organotitanium compound, an organozirconium compound, and an organoaluminum compound, and from the reason that increase in refractive index can be suppressed, an organosilicon compound is more preferable. The hydrophobizing treatment agent may be used singly or in combination of two or more kinds thereof.

The organosilicon compound is preferably an organosilane compound. Examples of the organosilane compound include an alkylsilane compound, an alkoxysilane compound, a halogenated silane compound, an aminosilane compound, and a silazane compound.

The hydrophobizing treatment agent is preferably a compound represented by Formula (S-1), a compound represented by Formula (S-2), or a compound represented by Formula (S-3).

(Rs¹)ₙ₁-Si—(Xs¹)ₙ₂ (S-1)

In Formula (S-1), Rs¹ represents a hydrocarbon group, Xs¹ represents an alkoxy group, n1 represents an integer of 0 to 3, n2 represents an integer of 1 to 4, in a case where n1 is 2 or 3, n1 pieces of Rs¹'s may be the same or different from each other, in a case where n2 is 2 to 4, n2 pieces of Xs¹'s may be the same or different from each other, and n1+n2 is 4.

(Rs¹¹)ₙ₁₁—Si—(Xs¹¹)ₙ₁₂ (S-2)

In Formula (S-2), Rs¹¹ represents a hydrocarbon group, Xs¹¹ represents a hydrogen atom, a halogen atom, or NRx¹Rx², Rx¹ and Rx² each independently represent a hydrogen atom or a hydrocarbon group, n11 represents an integer of 1 to 3, n12 represents an integer of 1 to 3, in a case where n11 is 2 or 3, n11 pieces of Rs¹¹'s may be the same or different from each other, in a case where n12 is 2 r 3, n12 pieces of Xs¹¹'s may be the same or different from each other, and n11+n12 is 4.

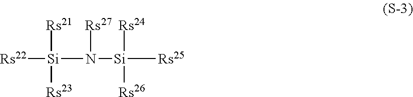

In Formula (S-3), Rs²¹ to Rs²⁶ each independently represent a hydrocarbon group, and Rs²⁷ represents a hydrogen atom or a hydrocarbon group.

Examples of the hydrocarbon group represented by Rs¹ in Formula (S-1) include an alkyl group, an alkenyl group, an alkynyl group, and an aryl group, and from the reason that it is easy to form a film with suppressed defects, an alkyl group is preferable.

The alkyl group preferably has 1 to 10 carbon atoms, more preferably has 1 to 5 carbon atoms, still more preferably has 1 to 3 carbon atoms, even more preferably has 1 or 2 carbon atoms, and particularly preferably has 1 carbon atom. Examples of the alkyl group include a linear alkyl group, a branched alkyl group, and a cyclic alkyl group, and a linear alkyl group or a branched alkyl group is preferable and a linear alkyl group is more preferable.

The alkenyl group preferably has 2 to 10 carbon atoms, more preferably has 2 to 5 carbon atoms, still more preferably has 2 or 3 carbon atoms, and even more preferably has 2 carbon atoms. The alkenyl group is preferably linear or branched, and more preferably linear.

The alkynyl group preferably has 2 to 10 carbon atoms, more preferably has 2 to 5 carbon atoms, still more preferably has 2 or 3 carbon atoms, and even more preferably has 2 carbon atoms. The alkynyl group is preferably linear or branched, and more preferably linear.

The aryl group preferably has 6 to 20 carbon atoms, more preferably has 6 to 12 carbon atoms, still more preferably has 6 to 10 carbon atoms, and even more preferably has 6 carbon atoms.

The alkyl group, alkenyl group, alkynyl group, and aryl group may further have a substituent. Examples of the substituent include a halogen atom and an alkyl group.

The alkoxy group represented by Xs¹ in Formula (S-1) preferably has 1 to 10 carbon atoms, more preferably has 1 to 5 carbon atoms, and still more preferably has 1 to 3 carbon atoms. The alkoxy group is preferably linear or branched, and more preferably linear.

n1 in Formula (S-1) represents an integer of 0 to 3, preferably an integer of 1 to 3, more preferably 2 or 3, and still more preferably 3. n2 represents an integer of 1 to 4, preferably an integer of 1 to 3, more preferably 1 or 2, and still more preferably 1.

Specific examples of the compound represented by Formula (S-1) include methyltrimethoxysilane, ethyltrimethoxysilane, propyltrimethoxysilane, phenyltrimethoxysilane, methyltriethoxysilane, ethyltriethoxysilane, phenyltriethoxysilane, dimethyldimethoxysilane, dimethyldiethoxysilane, trimethylmethoxysilane, triethylmethoxysilane, tripropylmethoxysilane, trimethylethoxysilane, triethylethoxysilane, tripropylethoxysilane, tetramethoxysilane, and tetraethoxysilane.

Examples of the hydrocarbon group represented by Rs¹¹ in Formula (S-2) include an alkyl group, an alkenyl group, an alkynyl group, and an aryl group, and from the reason that it is easy to form a film with suppressed defects, an alkyl group is preferable. Details of the hydrocarbon group represented by Rs¹¹ are the same as those of the hydrocarbon group represented by Rs¹ in Formula (S-1), and the preferred range thereof is also the same.

As the halogen atom represented by Xs¹¹ in Formula (S-2), a fluorine atom, a chlorine atom, or a bromine atom is preferable, and a chlorine atom is more preferable.

Examples of the hydrocarbon group represented by Rx¹ and Rx² in a case where Xs¹¹ in Formula (S-2) is NRx¹Rx² include an alkyl group, an alkenyl group, an alkynyl group, and an aryl group, and an alkyl group is preferable. Details of the hydrocarbon group represented by Rx¹ and Rx² are the same as those of the hydrocarbon group represented by Rs¹ in Formula (S-1), and the preferred range thereof is also the same. Rx¹ and Rx² are each independently preferably a hydrogen atom.

n11 in Formula (S-2) represents an integer of 1 to 3, preferably 2 or 3 and more preferably 3. n12 represents an integer of 1 to 3, and is preferably 1 or 2 and more preferably 1.

Specific examples of the compound represented by Formula (S-2) include trimethylsilane, trimethylchlorosilane, trimethylaminosilane, diethylaminotrimethylsilane, triethylsilane, and triethylchlorosilane.

Examples of the hydrocarbon group represented by Rs²¹ to Rs²⁷ in Formula (S-3) include an alkyl group, an alkenyl group, an alkynyl group, and an aryl group, and from the reason that it is easy to form a film with suppressed defects, an alkyl group is preferable. Details of the hydrocarbon group represented by Rs²¹ to Rs²⁷ are the same as those of the hydrocarbon group represented by Rs¹ in Formula (S-1), and the preferred range thereof is also the same. In Formula (S-3), it is preferable that Rs²¹ to Rs²⁶ each independently represent an alkyl group and Rs²⁷ represents a hydrogen atom.

Specific examples of the compound represented by Formula (S-3) include hexamethyldisilazane.

The CLog P value of the hydrophobizing treatment agent is preferably 0.0 to 10.0. From the viewpoint of hydrophobizing effect, the lower limit is preferably 0.1 or more and more preferably 0.5 or more. From the viewpoint of compatibility with silica, the upper limit is preferably 5.0 or less and more preferably 2.5 or less.

Here, the Clog P value is a calculated value of log P which is a common logarithm of a partition coefficient P of 1-octanol/water. The larger Clog P value of a material means that the material is hydrophobic. In the present specification, the Clog P value is a value calculated by the program “CLOGP” available from Daylight Chemical Information System, Inc. This program provides a value of “calculated Log P” calculated by Hansch, Leo's fragment approach (refer to the following reference). The fragment approach is based on a chemical structure of a compound, which estimates the Log P value of the compound by dividing the chemical structure into partial structures (fragments) and summing up the Log P contributions assigned to the fragments. In the present specification, as the fragment value, Fragment database ver. 23 (Biobyte) is used. Examples of the calculation software include Bio Loom ver. 1.5.

The molecular weight of the hydrophobizing treatment agent is preferably 50 to 1000. The lower limit is preferably 70 or more and more preferably 80 or more. The upper limit is preferably 500 or less and more preferably 200 or less.

The contact angle of a film, which is formed of the silica particles A and has a thickness of 0.4 μm, with water at 25° C. is preferably 20° to 90°, more preferably 30° to 85°, and still more preferably 40° to 80°. The contact angle is a value measured using a contact angle meter (DM-701, manufactured by Kyowa Interface Science Co., Ltd.).

The content of the silica particles A in the composition according to the embodiment of the present invention is preferably 4 mass % or more, more preferably 6 mass % or more, and still more preferably 7 mass % or more. The upper limit is preferably 15 mass % or less, more preferably 13 mass % or less, and still more preferably 11 mass % or less.

In addition, the content of the silica particles A in the total solid content of composition according to the embodiment of the present invention is preferably 50 mass % or more, more preferably 60 mass % or more, and still more preferably 70 mass % or more. The upper limit may be 99.95 mass % or less, 99.9 mass % or less, 99 mass % or less, or 95 mass % or less. In a case where the content of the silica particles A is within the above-described range, it is easy to obtain a film having a low refractive index and a high antireflection effect. In addition, in a case where pattern formation is not performed or a case where pattern formation is performed by an etching method, it is preferable that the content of the silica particles A in the total solid content of the composition according to the embodiment of the present invention is high, and for example, it is preferable to be 95 mass % or more, it is more preferable to be 97 mass % or more, and it is still more preferable to be 99 mass % or more.

<<Alkoxysilane Hydrolyzate>>

The composition according to the embodiment of the present invention preferably includes at least one component selected from the group consisting of alkoxysilane and a hydrolyzate of alkoxysilane (referred to as an alkoxysilane hydrolyzate). In a case where the composition according to the embodiment of the present invention further includes an alkoxysilane hydrolyzate, it is possible to firmly bond silica particles to each other during film formation and to exhibit effect of improving a void volume in the film during film formation. In addition, by using the alkoxysilane hydrolyzate, wettability of a surface of the film can be improved. The alkoxysilane hydrolyzate is preferably produced by condensation by hydrolysis of an alkoxysilane compound, and more preferably produced by condensation of an alkoxysilane compound and an alkoxysilane compound containing a fluoroalkyl group by hydrolysis. Examples of the alkoxysilane hydrolyzate include alkoxysilane hydrolyzates described in paragraph Nos. 0022 to 0027 of WO2015/190374A, the contents of which are incorporated herein by reference. In a case where the composition according to the embodiment of the present invention includes an alkoxysilane hydrolyzate, the total content of the silica particles A and the alkoxysilane hydrolyzate is preferably 0.1 mass % or more, more preferably 1 mass % or more, and particularly preferably 2 mass % or more with respect to the total solid content of the composition. The upper limit is preferably 99.99 mass % or less, more preferably 99.95 mass % or less, and particularly preferably 99.9 mass % or less.

<<Surfactant>>

The composition according to the embodiment of the present invention preferably contains a surfactant. By containing the surfactant, application properties of the composition are improved, and it is easy to form a film having excellent film thickness uniformity. Examples of the surfactant include a nonionic surfactant, a cationic surfactant, and an anionic surfactant, and a nonionic surfactant or a cationic surfactant is preferable and a nonionic surfactant is more preferable.

In addition, as the nonionic surfactant, a fluorine-based surfactant or a silicone-based surfactant is preferable, and from the reason that it is easy to obtain more excellent film thickness uniformity, a silicone-based surfactant is more preferable. In the present specification, the silicone-based surfactant is a compound having a repeating unit including a siloxane bond in the main chain, and is a compound including a hydrophobic part and a hydrophilic part in one molecule.

(Silicone-Based Surfactant)

The silicone-based surfactant is preferably a compound which does not include a fluorine atom. In addition, as the silicone-based surfactant, in a case where a solution is prepared by dissolving 0.1 g of a silicone-based surfactant in 100 g of propylene glycol monomethyl ether acetate, it is preferable that the surface tension of this solution at 25° C. is 19.5 to 26.7 mN/m.

The kinematic viscosity of the silicone-based surfactant at 25° C. is preferably 20 to 3000 mm²/s. The lower limit of the kinematic viscosity is preferably 22 mm²/s or more, more preferably 25 mm²/s or more, and still more preferably 30 mm²/s or more. The upper limit of the kinematic viscosity is preferably 2500 mm²/s or less, more preferably 2000 mm²/s or less, and still more preferably 1500 mm²/s or less. In a case where the kinematic viscosity of the silicone-based surfactant is within the above-described range, it is easy to obtain more excellent application properties, and it is easy to form a film in which generation of thickness unevenness or defects is further suppressed.

The weight-average molecular weight of the silicone-based surfactant is preferably 500 to 50000. The lower limit of the weight-average molecular weight is preferably 600 or more, more preferably 700 or more, and still more preferably 800 or more. The upper limit of the weight-average molecular weight is preferably 40000 or less, more preferably 30000 or less, and still more preferably 20000 or less.

The silicone-based surfactant is preferably a modified silicone compound. Examples of the modified silicone compound include compounds having a structure in which an organic group is introduced into a side chain and/or a terminal of polysiloxane. Examples of the organic group include a group including a functional group selected from an amino group, an epoxy group, an alicyclic epoxy group, a carbinol group, a mercapto group, a carboxy group, a fatty acid ester group, and a fatty acid amide group, and a group including a polyether chain, and from the reason that it is easy to form a film in which generation of thickness unevenness or defects is further suppressed, a group including a carbinol group or a group including a polyether chain is preferable.

Examples of the group including a carbinol group include a group represented by Formula (G-1).

-L^{G1}-CH₂OH (G-1)

In Formula (G-1), L^{G1} represents a single bond or a linking group. Examples of the linking group represented by L^{G1} include an alkylene group (preferably an alkylene group having 1 to 12 carbon atoms and more preferably an alkylene group having 1 to 6 carbon atoms), an arylene group (preferably an arylene group having 6 to 20 carbon atoms and more preferably an arylene group having 6 to 12 carbon atoms), —NH—, —SO—, —SO₂—, —CO—, —O—, —COO—, —OCO—, —S—, and a group including a combination of two or more thereof.

The group including a carbinol group is preferably a group represented by Formula (G-2).

-L^{G2}-O-L^{G3}-CH₂OH (G-2)

In Formula (G-2), L^{G2} and L^{G3} each independently represent a single bond or an alkylene group (preferably an alkylene group having 1 to 12 carbon atoms and more preferably an alkylene group having 1 to 6 carbon atoms), and preferably represent an alkylene group.

Examples of the group including a polyether chain include a group represented by Formula (G-11) and a group represented by Formula (G-12).

-L^{G11}-(R^{G1}O)ₙ₁R^{G2} (G-11)

-L^{G11}-(OR^{G1})ₙ₁OR^{G2} (G-12)

In Formula (G-11) and Formula (G-12), L^{G11} represents a single bond or a linking group. Examples of the linking group represented by L^{G11} include an alkylene group (preferably an alkylene group having 1 to 12 carbon atoms and more preferably an alkylene group having 1 to 6 carbon atoms), an arylene group (preferably an arylene group having 6 to 20 carbon atoms and more preferably an arylene group having 6 to 12 carbon atoms), —NH—, —SO—, —SO₂—, —CO—, —O—, —COO—, —OCO—, —S—, and a group including a combination of two or more thereof.

In Formula (G-11) and Formula (G-12), n1 represents a number of 2 or more, and is preferably 2 to 200.

In Formula (G-11) and Formula (G-12), R^{G1} represents an alkylene group. The alkylene group preferably has 1 to 10 carbon atoms, more preferably has 1 to 5 carbon atoms, still more preferably has 1 to 3 carbon atoms, and particularly preferably has 2 or 3 carbon atoms. The alkylene group represented by R^{G1} may be linear or branched. The alkylene groups represented by n1 pieces of R^{G1}'s may be the same or different from each other.

In Formula (G-11) and Formula (G-12), R^{G2} represents a hydrogen atom, an alkyl group, or an aryl group. The alkyl group represented by R^{G2} preferably has 1 to 10 carbon atoms, more preferably has 1 to 5 carbon atoms, and still more preferably has 1 to 3 carbon atoms. The alkyl group may be linear or branched. The aryl group represented by R^{G2} preferably has 6 to 20 carbon atoms and more preferably has 6 to 10 carbon atoms.

The group including a polyether chain is preferably a group represented by Formula (G-13) or a group represented by (G-14).

L^{G12}-(C₂H₄O)ₙ₂(C₃H₆O)ₙ₃R^{G3} (G-13)

L^{G12}-(OC₂H₄)ₙ₂(OC₃H₆)ₙ₃OR^{G3} (G-14)

In Formula (G-13) and Formula (G-14), L^{G12} represents a single bond or a linking group. Examples of the linking group represented by L^{G12} include an alkylene group (preferably an alkylene group having 1 to 12 carbon atoms and more preferably an alkylene group having 1 to 6 carbon atoms), an arylene group (preferably an arylene group having 6 to 20 carbon atoms and more preferably an arylene group having 6 to 12 carbon atoms), —NH—, —SO—, —SO₂—, —CO—, —O—, —COO—, —OCO—, —S—, and a group including a combination of two or more thereof.

In Formula (G-13) and Formula (G-14), n2 and n3 each independently represent a number of 1 or more, and are preferably 1 to 100.

In Formula (G-13) and Formula (G-14), R^{G3} represents a hydrogen atom, an alkyl group, or an aryl group. The alkyl group represented by R^{G3} preferably has 1 to 10 carbon atoms, more preferably has 1 to 5 carbon atoms, and still more preferably has 1 to 3 carbon atoms. The alkyl group may be linear or branched. The aryl group represented by R^{G3} preferably has 6 to 20 carbon atoms and more preferably has 6 to 10 carbon atoms.

The modified silicone compound is preferably a compound represented by Formulae (Si-1) to (Si-5).

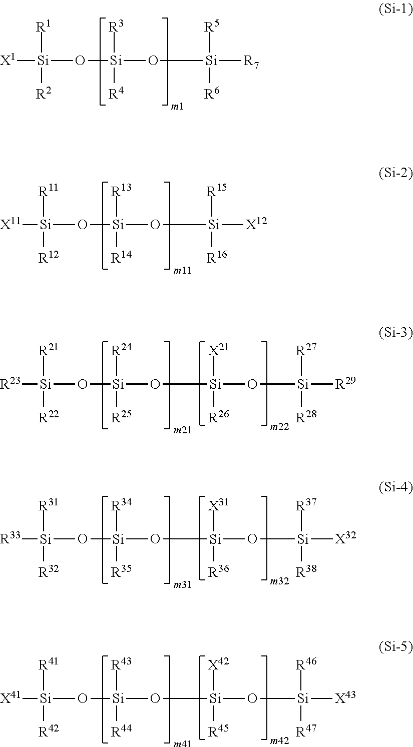

In Formula (Si-1), R¹ to R⁷ each independently represent an alkyl group or an aryl group, X¹ represents a group including a functional group selected from an amino group, an epoxy group, an alicyclic epoxy group, a carbinol group, a mercapto group, a carboxy group, a fatty acid ester group, and a fatty acid amide group, or a group including a polyether chain, m1 represents a number of 2 to 200.

The alkyl group represented by R¹ to R⁷ preferably has 1 to 10 carbon atoms, more preferably has 1 to 5 carbon atoms, still more preferably has 1 to 3 carbon atoms, and particularly preferably has 1 carbon atom. The alkyl group represented by R¹ to R⁷ may be linear or branched, but is preferably linear. The aryl group represented by R¹ to R⁷ preferably has 6 to 20 carbon atoms, more preferably has 6 to 12 carbon atoms, and particularly preferably has 6 carbon atoms. R¹ to R⁷ are each independently preferably a methyl group or a phenyl group, and more preferably a methyl group.

X¹ is preferably a group including a carbinol group or a group including a polyether chain, and more preferably a group including a carbinol group. The preferred range of the group including a carbinol group and the group including a polyether chain is the same as the above-described range.

In Formula (Si-2), R¹¹ to R¹⁶ each independently represent an alkyl group or an aryl group, X¹¹ and X¹² each independently represent a group including a functional group selected from an amino group, an epoxy group, an alicyclic epoxy group, a carbinol group, a mercapto group, a carboxy group, a fatty acid ester group, and a fatty acid amide group, or a group including a polyether chain, m11 represents a number of 2 to 200.

R¹¹ to R¹⁶ in Formula (Si-2) have the same meanings as R¹ to R⁷ in Formula (Si-1), and preferred ranges thereof are also the same. X¹¹ and X¹² in Formula (Si-2) have the same meanings as X¹ in Formula (Si-1), and preferred ranges thereof are also the same.

In Formula (Si-3), R²¹ to R²⁹ each independently represent an alkyl group or an aryl group, X²¹ represents a group including a functional group selected from an amino group, an epoxy group, an alicyclic epoxy group, a carbinol group, a mercapto group, a carboxy group, a fatty acid ester group, and a fatty acid amide group, or a group including a polyether chain, m21 and m22 each independently represent a number of 1 to 199, and in a case where m22 is 2 or more, m22 pieces of X²¹'s may be the same or different from each other.

R²¹ to R²⁹ in Formula (Si-3) have the same meanings as R¹ to R⁷ in Formula (Si-1), and preferred ranges thereof are also the same. X²¹ in Formula (Si-3) have the same meanings as X¹ in Formula (Si-1), and preferred ranges thereof are also the same.

In Formula (Si-4), R³¹ to R³⁸ each independently represent an alkyl group or an aryl group, X³¹ and X³² each independently represent a group including a functional group selected from an amino group, an epoxy group, an alicyclic epoxy group, a carbinol group, a mercapto group, a carboxy group, a fatty acid ester group, and a fatty acid amide group, or a group including a polyether chain, m31 and m32 each independently represent a number of 1 to 199, and in a case where m32 is 2 or more, m32 pieces of X³¹'s may be the same or different from each other.

R³¹ to R³⁸ in Formula (Si-4) have the same meanings as R¹ to R⁷ in Formula (Si-1), and preferred ranges thereof are also the same. X³¹ and X³² in Formula (Si-4) have the same meanings as X¹ in Formula (Si-1), and preferred ranges thereof are also the same.

In Formula (Si-5), R⁴¹ to R⁴⁷ each independently represent an alkyl group or an aryl group, X⁴¹ to X⁴³ each independently represent a group including a functional group selected from an amino group, an epoxy group, an alicyclic epoxy group, a carbinol group, a mercapto group, a carboxy group, a fatty acid ester group, and a fatty acid amide group, or a group including a polyether chain, m41 and m42 each independently represent a number of 1 to 199, and in a case where m42 is 2 or more, m42 pieces of X⁴²'s may be the same or different from each other.

R⁴¹ to R⁴⁷ in Formula (Si-5) have the same meanings as R¹ to R⁷ in Formula (Si-1), and preferred ranges thereof are also the same. X⁴¹ to X⁴³ in Formula (Si-5) have the same meanings as X¹ in Formula (Si-1), and preferred ranges thereof are also the same.

Specific examples of the silicone-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), Silwet L-77, L-7280, L-7001, L-7002, L-7200, L-7210, L-7220, L-7230, L7500, L-7600, L-7602, L-7604, L-7605, L-7622, L-7657, L-8500, and L-8610 (all of which are manufactured by Momentive Performance Materials Co., Ltd.), KP-341, KF-6001, and KF-6002 (all of which are manufactured by Shin-Etsu Silicone Co., Ltd.), and BYK307, BYK323, and BYK330 (all of which are manufactured by BYK Chemie).

(Fluorine-Based Surfactant)

The fluorine-based surfactant is preferably a polymer surfactant having a polyethylene main chain. Among these, a polymer surfactant having a poly(meth)acrylate structure is preferable. Among these, in the present invention, a copolymer including a (meth)acrylate constitutional unit having the above-described polyoxyalkylene structure and a fluoroalkyl acrylate constitutional unit is preferable.

In addition, as the fluorine-based surfactant, a compound having a fluoroalkyl group or fluoroalkylene group (preferably having 1 to 24 carbon atoms and more preferably having 2 to 12 carbon atoms) at any of moieties can be suitably used. Preferably, a polymer compound having the above-described fluoroalkyl group or fluoroalkylene group in the side chain can be used. The fluorine-based surfactant preferably further has the above-described polyoxyalkylene structure, and more preferably has the polyoxyalkylene structure in the side chain. Examples of the compound having a fluoroalkyl group or fluoroalkylene group include compounds described in paragraphs 0034 to 0040 of WO2015/190374A, the contents of which are incorporated herein by reference.

Examples of the fluorine-based surfactant include MEGAFACE F171, F172, F173, F176, F177, F141, F142, F143, F144, R30, F437, F479, F482, F554, F559, F780, and F781F (all of which are manufactured by DIC Corporation); FLUORAD FC430, FC431, and FC171 (all of which are manufactured by Sumitomo 3M Ltd.); SURFLON S-382, S-141, S-145, SC-101, SC-103, SC-104, SC-105, SC-1068, SC-381, SC-383, S-393, and KH-40 (all of which are manufactured by Asahi Glass Co., Ltd.); EFTOP EF301, EF303, EF351, and EF352 (all of which are manufactured by GEMCO Co., Ltd.); and PF636, PF656, PF6320, PF6520, and PF7002 (all of which are manufactured by OMNOVA Solutions Inc.).

In addition, a block polymer can also be used as the fluorine-based surfactant. Examples thereof include the compounds described in JP2011-089090A. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. The following compounds are also exemplified as the fluorine-based surfactant used in the present invention.

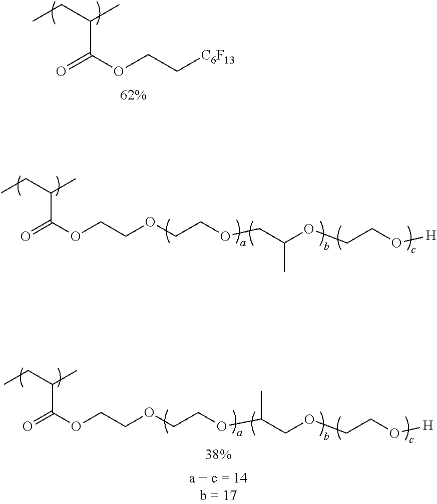

The weight-average molecular weight of the above-described compound is preferably 3000 to 50000, and is, for example, 14000. In the compound, “%” representing the proportion of a repeating unit is mol %.

(Other Nonionic Surfactants)

As a nonionic surfactant other than the fluorine-based surfactant and the silicone-based surfactant, a surfactant having a polyoxyalkylene structure can also be used. The polyoxyalkylene structure refers to a structure in which an alkylene group and a divalent oxygen atom are present adjacent to each other, and specific examples thereof include an ethylene oxide (EO) structure and a propylene oxide (PO) structure. The polyoxyalkylene structure may constitute a graft chain of an acrylic polymer.

(Cationic Surfactant)

Examples of the cationic surfactant include a compound having a plurality of cationic parts, which are hydrophilic moieties, and hydrophobic moieties in the same molecule. Examples of the cationic group of the hydrophilic part include an amino group or a salt thereof, a quaternary ammonium group or a salt thereof, a hydroxyammonium group or a salt thereof, an etherammonium group or a salt thereof, a pyridinium group or a salt thereof, an imidazolium group or a salt thereof, an imidazoline group or a salt thereof, and a phosphonium group or a salt thereof. Examples of the cationic surfactant include a quaternary ammonium salt-based surfactant, an alkylpyridium-based surfactant, and a polyallylamine-based surfactant. Specific examples of the cationic surfactant include dodecyltrimethylammonium chloride.

(Anionic Surfactant)

Examples of the anionic surfactant include W004, W005, and W017 (all of which are manufactured by Yusho Co., Ltd.), EMULSOGEN COL-020, EMULSOGEN COA-070, and EMULSOGEN COL-080 (all of which are manufactured by Clariant Japan), and PLYSURF A208B (manufactured by DKS Co., Ltd.). Examples of an anionic group include a carboxy group, a sulfonic acid group, a phosphonic acid group, and a phosphoric acid group. These acid groups may form a salt.

The content of the surfactant in the composition according to the embodiment of the present invention is preferably 0.01 to 3.0 mass %. The lower limit is preferably 0.02 mass % or more and more preferably 0.03 mass % or more. The upper limit is preferably 2.0 mass % or less, more preferably 1.5 mass % or less, and still more preferably 1.0 mass % or less.

In addition, the content of the surfactant in the total solid content of the composition according to the embodiment of the present invention is preferably 0.1 to 30 mass %. The lower limit is preferably 0.2 mass % or more and more preferably 0.3 mass % or more. The upper limit is preferably 20 mass % or less and more preferably 10 mass % or less.

In addition, it is preferable to contain 0.1 to 25 parts by mass of the surfactant with respect to 100 parts by mass of the silica particles A. The lower limit is preferably 0.2 parts by mass or more and more preferably 0.3 parts by mass or more. The upper limit is preferably 20 parts by mass or less, more preferably 15 parts by mass or less, and still more preferably 10 parts by mass or less.

In a case where the content of the surfactant is within the above-described range, application properties of the composition can be further improved, and it is easy to obtain more excellent film thickness uniformity. As the surfactant, one kind may be included, or two or more kinds may be included. In a case where two or more kinds thereof are included, the total amount thereof is preferably within the above-described range. In addition, in a case where two or more kinds of surfactants are used, a combination of the surfactants is not particularly limited, and two or more cationic surfactants may be used, two or more anionic surfactants may be used, two or more nonionic surfactants may be used, one or more cationic surfactants and one or more nonionic surfactants may be used, or one or more anionic surfactants and one or more nonionic surfactants may be used.

<<Solvent>>

The composition according to the embodiment of the present invention includes a solvent. Examples of the solvent include an organic solvent and water, and it is preferable to include at least an organic solvent. Examples of the organic solvent include an aliphatic hydrocarbon-based solvent, a halogenated hydrocarbon-based solvent, an alcohol-based solvent, an ether-based solvent, an ester-based solvent, a ketone-based solvent, a nitrile-based solvent, an amide-based solvent, a sulfoxide-based solvent, and an aromatic solvent.

Examples of the aliphatic hydrocarbon-based solvent include hexane, cyclohexane, methylcyclohexane, pentane, cyclopentane, heptane, and octane.

Examples of the halogenated hydrocarbon-based solvent include methylene chloride, chloroform, dichloromethane, ethane dichloride, carbon tetrachloride, trichlorethylene, tetrachlorethylene, epichlorohydrin, monochlorobenzene, o-dichlorobenzene, allyl chloride, methyl monochloroacetate, ethyl monochloroacetate, monochloroacetic acid, trichloroacetic acid, and methyl bromide.

Examples of the alcohol-based solvent include methanol, ethanol, 1-propanol, 2-propanol, 2-butanol, ethylene glycol, propylene glycol, glycerin, 1,6-hexanediol, cyclohexanediol, sorbitol, xylitol, 2-methyl-2,4-pentanediol, 3-methoxy-1-butanol, 1,3-butanediol, and 1,4-butanediol.

Examples of the ether-based solvent include dimethyl ether, diethyl ether, diisopropyl ether, dibutyl ether, t-butyl methyl ether, cyclohexylmethyl ether, anisole, tetrahydrofuran, diethylene glycol, triethylene glycol, polyethylene glycol, dipropylene glycol, ethylene glycol monomethyl ether, ethylene glycol monobutyl ether, ethylene glycol monophenyl ether, propylene glycol monomethyl ether, propylene glycol monoethyl ether, propylene glycol monopropyl ether, propylene glycol monobutyl ether, diethylene glycol monomethyl ether, diethylene glycol monoethyl ether, diethylene glycol monopropyl ether, diethylene glycol monobutyl ether, diethylene glycol dimethyl ether, diethylene glycol diethyl ether, diethylene glycol dipropyl ether, diethylene glycol dibutyl ether, dipropylene glycol monomethyl ether, dipropylene glycol dimethyl ether, dipropylene glycol monoethyl ether, dipropylene glycol monopropyl ether, dipropylene glycol monobutyl ether, dipropylene glycol methyl-n-propyl ether, triethylene glycol monomethyl ether, triethylene glycol monobutyl ether, tripropylene glycol monomethyl ether, tripropylene glycol monobutyl ether, tetraethylene glycol dimethyl ether, polyethylene glycol monomethyl ether, and polyethylene glycol dimethyl ether.

Examples of the ester-based solvent include propylene carbonate, dipropylene, 1,4-butanediol diacetate, 1,3-butylene glycol diacetate, 1,6-hexanediol diacetate, cyclohexanol acetate, dipropylene glycol methyl ether acetate, methyl acetate, ethyl acetate, isopropyl acetate, n-propyl acetate, butyl acetate, ethylene glycol monomethyl ether acetate, propylene glycol monomethyl ether acetate, 3-methoxybutyl acetate, ethylene glycol monobutyl ether acetate, diethylene glycol monoethyl ether acetate, diethylene glycol monobutyl ether acetate, and triacetin.

Examples of the ketone-based solvent include acetone, methyl ethyl ketone, methyl isobutyl ketone, cyclopentanone, cyclohexanone, and 2-heptanone.

Examples of the nitrile-based solvent include acetonitrile.

Examples of the amide-based solvent include N,N-dimethylformamide, 1-methyl-2-pyrrolidone, 2-pyrrolidinone, 1,3-dimethyl-2-imidazolidinone, ε-caprolactam, formamide, N-methylformamide, acetamide, N-methylacetamide, N,N-dimethylacetamide, N-methylpropaneamide, hexamethylphosphoric triamide, 3-methoxy-N,N-dimethylpropaneamide, and 3-butoxy-N,N-dimethylpropaneamide.

Examples of the sulfoxide-based solvent include dimethyl sulfoxide.

Examples of the aromatic solvent include benzene and toluene.

In the present invention, as the solvent, from the reason that it is easy to improve temporal stability of the composition, it is preferable to use a solvent including an alcohol-based solvent. The alcohol-based solvent is preferably at least one selected from methanol, ethanol, 1-propanol, 2-propanol, or 2-butanol, and more preferably at least one selected from methanol and ethanol. Among these, the alcohol-based solvent preferably includes at least methanol, and from the reason that it is easy to form a film in which generation of defects is suppressed, more preferably includes methanol and ethanol.

The content of the solvent in the composition according to the embodiment of the present invention is preferably 70 to 99 mass %. The upper limit is preferably 93 mass % or less, more preferably 92 mass % or less, and still more preferably 90 mass % or less. The lower limit is preferably 75 mass % or more, more preferably 80 mass % or more, and still more preferably 85 mass % or more.

In addition, the content of the alcohol-based solvent in the total amount of the solvent is preferably 0.1 to 10 mass %. The upper limit is preferably 8 mass % or less, more preferably 6 mass % or less, and still more preferably 4 mass % or less. The lower limit is preferably 0.3 mass % or more, more preferably 0.5 mass % or more, and still more preferably 1 mass % or more. In a case where the content of the alcohol-based solvent is within the above-described range, the above-described effects are easily obtained more remarkably. The alcohol-based solvent may be used singly or in combination of two or more kinds thereof. In a case where the composition according to the embodiment of the present invention includes two or more kinds of alcohol-based solvents, it is preferable that the total amount thereof is within the above-described range.

In the present invention, it is preferable to use, as the solvent, a solvent including a solvent A1 having a boiling point of 190° C. to 280° C. In the present specification, the boiling point of a solvent is a value at 1 atm (0.1 MPa).

The boiling point of the solvent A1 is preferably 200° C. or higher, more preferably 210° C. or higher, and still more preferably 220° C. or higher. In addition, the boiling point of the solvent A1 is preferably 270° C. or lower and still more preferably 265° C. or lower.

The viscosity of the solvent A1 is preferably 10 mPa·s or less, more preferably 7 mPa·s or less, and still more preferably 4 mPa·s or less. From the viewpoint of application properties, the lower limit of the viscosity of the solvent A1 is preferably 1.0 mPa·s or more, more preferably 1.4 mPa·s or more, and still more preferably 1.8 mPa·s or more.

The molecular weight of the solvent A1 is preferably 100 or more, more preferably 130 or more, still more preferably 140 or more, and particularly preferably 150 or more. From the viewpoint of application properties, the upper limit is preferably 300 or less, more preferably 290 or less, still more preferably 280 or less, and particularly preferably 270 or less.

The solubility parameter of the solvent A1 is preferably 8.5 to 13.3 (cal/cm³)^{0.5}. The upper limit is preferably 12.5 (cal/cm³)^{0.5} or less, more preferably 11.5 (cal/cm³)^{0.5} or less, and still more preferably 10.5 (cal/cm³)^{0.5} or less. The lower limit is preferably 8.7 (cal/cm³)^{0.5} or more, more preferably 8.9 (cal/cm³)^{0.5} or more, and still more preferably 9.1 (cal/cm³)^{0.5} or more. In a case where the solubility parameter of the solvent A1 is within the above-described range, high affinity with the silica particles A can be obtained, and excellent application properties can be easily obtained. 1 (cal/cm³)^{0.5} is 2.0455 MPa^{0.5}. In addition, the solubility parameter of a solvent is a value calculated by HSPiP.

In the present specification, the Hansen solubility parameter is used as the solubility parameter of the solvent. Specifically, a value calculated by using the Hansen solubility parameter software “HSPiP 5.0.09” is used.

The solvent A1 is preferably an aprotic solvent. By using an aprotic solvent as the solvent A1, aggregation of the silica particles A during film formation can be suppressed more effectively, and it is easy to form a film in which generation of defects is further suppressed.

The solvent A1 is preferably an ether-based solvent or an ester-based solvent, and more preferably an ester-based solvent. In addition, the ester-based solvent used as the solvent A1 is preferably a compound not including a hydroxy group or a terminal alkoxy group. By using an ester-based solvent not having such a functional group, it is easy to form a film in which generation of defects is further suppressed.

From the reason that high affinity with the silica particles A can be obtained and excellent application properties can be easily obtained, the solvent A1 is preferably at least one selected from alkylenediol diacetate and cyclic carbonate. Examples of the alkylenediol diacetate include propylene glycol diacetate, 1,4-butanediol diacetate, 1,3-butylene glycol diacetate, and 1,6-hexanediol diacetate. Examples of the cyclic carbonate include propylene carbonate and ethylene carbonate.

Specific examples of the solvent A1 include propylene carbonate (boiling point: 240° C.), ethylene carbonate (boiling point: 260° C.), propylene glycol diacetate (boiling point: 190° C.), dipropylene glycol methyl-n-propyl ether (boiling point: 203° C.), dipropylene glycol methyl ether acetate (boiling point: 213° C.), 1,4-butanediol diacetate (boiling point: 232° C.), 1,3-butylene glycol diacetate (boiling point: 232° C.), 1,6-hexanediol diacetate (boiling point: 260° C.), diethylene glycol monoethyl ether acetate (boiling point: 217° C.), diethylene glycol monobutyl ether acetate (boiling point: 247° C.), triacetin (boiling point: 260° C.), dipropylene glycol monomethyl ether (boiling point: 190° C.), diethylene glycol monoethyl ether (boiling point: 202° C.), dipropylene glycol monopropyl ether (boiling point: 212° C.), dipropylene glycol monobutyl ether (boiling point: 229° C.), tripropylene glycol monomethyl ether (boiling point: 242° C.), and tripropylene glycol monobutyl ether (boiling point: 274° C.).

The solvent used in the composition according to the embodiment of the present invention preferably contains 3 mass % or more of the above-described solvent A1, more preferably contains 4 mass % or more thereof, and still more preferably contains 5 mass % or more thereof. According to this aspect, the above-described effects of the present invention are easily obtained remarkably. The upper limit is preferably 20 mass % or less, more preferably 15 mass % or less, and still more preferably 12 mass % or less. The solvent A1 may be used singly or in combination of two or more kinds thereof. In a case where the composition according to the embodiment of the present invention includes two or more kinds of the solvent A1, it is preferable that the total amount thereof is within the above-described range.

In addition to the above-described solvent A1, the solvent used in the composition according to the embodiment of the present invention preferably further contains a solvent A2 having a boiling point of 110° C. or higher and lower than 190° C. According to this aspect, it is easy to form a film in which drying properties of the composition are appropriately increased and the thickness unevenness is suppressed.

The boiling point of the solvent A2 is preferably 115° C. or higher, more preferably 120° C. or higher, and still more preferably 130° C. or higher. In addition, the boiling point of the solvent A2 is preferably 170° C. or lower and still more preferably 150° C. or lower. In a case where the boiling point of the solvent A2 is within the above-described range, the above-described effects are easily obtained more remarkably.

From the reason that the above-described effects are easily obtained more remarkably, the molecular weight of the solvent A2 is preferably 100 or more, more preferably 130 or more, still more preferably 140 or more, and particularly preferably 150 or more. From the viewpoint of application properties, the upper limit is preferably 300 or less, more preferably 290 or less, still more preferably 280 or less, and particularly preferably 270 or less.

The solubility parameter of the solvent A2 is preferably 9.0 to 11.4 (cal/cm³)^{0.5} The upper limit is preferably 11.0 (cal/cm³)^{0.5} or less, more preferably 10.6 (cal/cm³)^{0.5} or less, and still more preferably 10.2 (cal/cm³)^{0.5} or less. The lower limit is preferably 9.2 (cal/cm³)^{0.5} or more, more preferably 9.4 (cal/cm³)^{0.5} or more, and still more preferably 9.6 (cal/cm³)^{0.5} or more. In a case where the solubility parameter of the solvent A2 is within the above-described range, high affinity with the silica particles A can be obtained, and excellent application properties can be easily obtained. In addition, the absolute value of a difference between the solubility parameter of the solvent A1 and the solubility parameter of the solvent A2 is preferably 0.01 to 1.1 (cal/cm³)^{0.5}. The upper limit is preferably 0.9 (cal/cm³)^{0.5} or less, more preferably 0.7 (cal/cm³)^{0.5} or less, and still more preferably 0.5 (cal/cm³)^{0.5} or less. The lower limit is preferably 0.03 (cal/cm³)^{0.5} or more, more preferably 0.05 (cal/cm³)^{0.5} or more, and still more preferably 0.08 (cal/cm³)^{0.5} or more.

The solvent A2 is preferably at least one selected from an ether-based solvent or an ester-based solvent, more preferably includes at least an ester-based solvent, and still more preferably includes an ether-based solvent and an ester-based solvent. Specific examples of the solvent A2 include cyclohexanol acetate (boiling point: 173° C.), dipropylene glycol dimethyl ether (boiling point: 175° C.), butyl acetate (boiling point: 126° C.), ethylene glycol monomethyl ether acetate (boiling point: 145° C.), propylene glycol monomethyl ether acetate (boiling point: 146° C.), 3-methoxybutyl acetate (boiling point: 171° C.), propylene glycol monomethyl ether (boiling point: 120° C.), 3-methoxybutanol (boiling point: 161° C.), propylene glycol monopropyl ether (boiling point: 150° C.), propylene glycol monobutyl ether (boiling point: 170° C.), and ethylene glycol monobutyl ether acetate (boiling point: 188° C.), and from the reason that high affinity with the silica particles A can be obtained and excellent application properties can be easily obtained, it is preferable to include at least propylene glycol monomethyl ether acetate.

In a case where the solvent used in the composition according to the embodiment of the present invention contains a solvent A2, the content of the solvent A2 is preferably 500 to 5000 parts by mass with respect to 100 parts by mass of the solvent A1. The upper limit is preferably 4500 parts by mass or less, more preferably 4000 parts by mass or less, and still more preferably 3500 parts by mass or less. The lower limit is preferably 600 parts by mass or more, more preferably 700 parts by mass or more, and still more preferably 750 parts by mass or more. In addition, the content of the solvent A2 in the total amount of the solvent is preferably 50 mass % or more, more preferably 60 mass % or more, and still more preferably 70 mass % or more. The upper limit is preferably 95 mass % or less, more preferably 90 mass % or less, and still more preferably 85 mass % or less. In a case where the content of the solvent A2 is within the above-described range, the effects of the present invention are easily obtained more remarkably. The solvent A2 may be used singly or in combination of two or more kinds thereof. In a case where the composition according to the embodiment of the present invention includes two or more kinds of the solvent A2, it is preferable that the total amount thereof is within the above-described range.

In addition, the solvent used in the composition according to the embodiment of the present invention preferably contains 62 mass % or more of the total of the solvent A1 and the solvent A2, more preferably contains 72 mass % or more thereof, and still more preferably contains 82 mass % or more thereof. The upper limit may be 100 mass %, 96 mass % or less, or 92 mass % or less.

It is also preferable that the solvent used in the composition according to the embodiment of the present invention further contains water. According to this aspect, high affinity with the silica particles A can be obtained, and excellent application properties can be easily obtained. In a case where the solvent used in the composition according to the embodiment of the present invention further contains water, the content of water in the total amount of the solvent is preferably 0.1 to 5 mass %. The upper limit is preferably 4 mass % or less, more preferably 2.5 mass % or less, and still more preferably 1.5 mass % or less. The lower limit is preferably 0.3 mass % or more, more preferably 0.5 mass % or more, and still more preferably 0.7 mass % or more. In a case where the content of water is within the above-described range, the above-described effects are easily obtained more remarkably.

The solvent used in the composition according to the embodiment of the present invention can further contain a solvent A3 having a boiling point of higher than 280° C. According to this aspect, it is easy to form a film in which drying properties of the composition are appropriately increased and generation of thickness unevenness or defects is further suppressed. The upper limit of the boiling point of the solvent A3 is preferably 400° C. or lower, more preferably 380° C. or lower, and still more preferably 350° C. or lower. The solvent A3 is preferably at least one selected from an ether-based solvent or an ester-based solvent. Specific examples of the solvent A3 include polyethylene glycol monomethyl ether. In a case where the solvent used in the composition according to the embodiment of the present invention further contains a solvent A3, the content of the solvent A3 in the total amount of the solvent is preferably 0.5 to 15 mass %. The upper limit is preferably 10 mass % or less, more preferably 8 mass % or less, and still more preferably 6 mass % or less. The lower limit is preferably 1 mass % or more, more preferably 1.5 mass % or more, and still more preferably 2 mass % or more. In addition, it is also preferable that the solvent used in the composition according to the embodiment of the present invention does not substantially contain the solvent A3. The case where the solvent does not substantially contain the solvent A3 means that the content of the solvent A3 in the total amount of the solvent is 0.1 mass % or less, preferably 0.05 mass % or less, more preferably 0.01 mass % or less, and still more preferably 0 mass %.

In the solvent used in the composition according to the embodiment of the present invention, the content of a compound having a molecular weight (weight-average molecular weight in a case of a polymer) of more than 300 is preferably 10 mass % or less, more preferably 8 mass % or less, still more preferably 5 mass % or less, even more preferably 3 mass % or less, and particularly preferably 1 mass % or less. According to this aspect, it is easy to form a film in which generation of thickness unevenness or defects is further suppressed.

In the solvent used in the composition according to the embodiment of the present invention, the content of a compound having a viscosity of more than 10 mPa·s at 25° C. is preferably 10 mass % or less, more preferably 8 mass % or less, still more preferably 5 mass % or less, even more preferably 3 mass % or less, and particularly preferably 1 mass % or less. According to this aspect, it is easy to form a film in which generation of thickness unevenness or defects is further suppressed.

<<Dispersant>>

The composition according to the embodiment of the present invention can contain a dispersant. Examples of the dispersant include polymer dispersants (for example, polyamide amine or a salt thereof, polycarboxylic acid or a salt thereof, high molecular weight unsaturated acid ester, modified polyurethane, modified polyester, modified poly(meth)acrylate, a (meth)acrylic copolymer, and a naphthalene sulfonic acid formalin condensate), polyoxyethylene alkylphosphate ester, polyoxyethylene alkyl amine, and alkanolamine. The polymer dispersant can be further classified into a linear polymer, a terminal-modified polymer, a graft polymer, and a block polymer according to the structure thereof. The polymer dispersant adsorbs on a surface of particles and acts to prevent reaggregation. Therefore, examples of a preferred structure of the polymer dispersant include a terminal-modified polymer, a graft polymer, and a block polymer, each of which has an anchor site for adsorbing on the particle surface. A commercially available product can also be used as the dispersant. Examples thereof include products described in paragraph No. 0050 of WO2016/190374A, the contents of which are incorporated herein by reference.

The content of the dispersant is preferably 1 to 100 parts by mass, more preferably 3 to 100 parts by mass, and still more preferably 5 to 80 parts by mass with respect to 100 parts by mass of the silica particles A. In addition, the content of the dispersant in the total solid content of the composition is preferably 1 to 30 mass %. As the dispersant, one kind may be included, or two or more kinds may be included. In a case where the composition according to the embodiment of the present invention includes two or more kinds of dispersants, it is preferable that the total amount thereof is within the above-described range.

<<Polymerizable Compound>>

The composition according to the embodiment of the present invention can contain a polymerizable compound. As the polymerizable compound, a known compound which is cross-linkable by a radical, an acid, or heat can be used. In the present invention, the polymerizable compound is preferably a radically polymerizable compound. The radically polymerizable compound is preferably a compound having an ethylenically unsaturated bonding group.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound having two or more ethylenically unsaturated bonding groups, and more preferably a compound having three or more ethylenically unsaturated bonding groups. The upper limit of the number of the ethylenically unsaturated bonding groups is, for example, preferably 15 or less and more preferably 6 or less. Examples of the ethylenically unsaturated bonding group include a vinyl group, a styrene group, a (meth)allyl group, and a (meth)acryloyl group. Among these, a (meth)acryloyl group is preferable. The polymerizable compound is preferably a trifunctional to pentadecafunctional (meth)acrylate compound and more preferably a trifunctional to hexafunctional (meth)acrylate compound. Specific examples of the polymerizable compound include compounds described in paragraph Nos. 0059 to 0079 of WO2016/190374A.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd. and NK ESTER A-DPH-12E manufactured by Shin-Nakamura Chemical Co., Ltd.), a compound having a structure in which a (meth)acryloyl group of these compounds is bonded through an ethylene glycol residue and/or a propylene glycol residue (for example, SR454 and SR499 available from Sartomer Japan Inc.), diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), or the like can be used. In addition, as the polymerizable compound, a compound having the following structure can also be used.

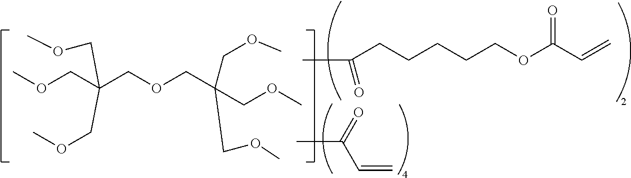

In addition, as the polymerizable compound, a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate can also be used. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a compound having an acid group can also be used. By using a polymerizable compound having an acid group, the polymerizable compound in a non-exposed portion is easily removed during development and the generation of a development residue can be suppressed. Examples of the acid group include a carboxy group, a sulfo group, and a phosphoric acid group, and a carboxy group is preferable. Examples of a commercially available product of the polymerizable compound having an acid group include ARONIX M-510, M-520, and ARONIX TO-2349 (manufactured by TOAGOSEI CO., LTD). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

As the polymerizable compound, a compound having a caprolactone structure can also be used. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

In a case where the composition according to the embodiment of the present invention contains a polymerizable compound, the content of the polymerizable compound in the composition according to the embodiment of the present invention is preferably 0.1 mass % or more, more preferably 0.2 mass % or more, and still more preferably 0.5 mass % or more. The upper limit is preferably 10 mass % or less, more preferably 5 mass % or less, and still more preferably 3 mass % or less. In addition, the content of the polymerizable compound in the total solid content of the composition according to the embodiment of the present invention is preferably 1 mass % or more, more preferably 2 mass % or more, and still more preferably 5 mass % or more. The upper limit is preferably 30 mass % or less, more preferably 25 mass % or less, and still more preferably 20 mass % or less. The composition according to the embodiment of the present invention may include only one kind of the polymerizable compound or two or more kinds thereof. In a case where the composition according to the embodiment of the present invention includes two or more kinds of polymerizable compounds, it is preferable that the total amount thereof is within the above-described range.

In addition, it is also preferable that the composition according to the embodiment of the present invention does not substantially include the polymerizable compound. In a case where the composition according to the embodiment of the present invention does not substantially include the polymerizable compound, it is easy to form a film having a lower refractive index. Furthermore, it is easy to form a film having a small haze. The case where the composition according to the embodiment of the present invention does not substantially include the polymerizable compound means that the content of the polymerizable compound in the total solid content of the composition according to the embodiment of the present invention is 0.05 mass % or less, preferably 0.01 mass % or less and more preferably 0 mass %.

<<Photopolymerization Initiator>>

In a case where the composition according to the embodiment of the present invention includes the polymerizable compound, it is preferable that the composition according to the embodiment of the present invention further includes a photopolymerization initiator. In a case where the composition according to the embodiment of the present invention includes the polymerizable compound and a photopolymerization initiator, the composition according to the embodiment of the present invention can be preferably used as a composition for forming a pattern by a photolithography method.

The photopolymerization initiator is not particularly limited as long as it has an ability to initiate the polymerization of the polymerizable compound, and can be appropriately selected from known photopolymerization initiators. In a case where a radically polymerizable compound is used as the polymerizable compound, it is preferable that a photoradical polymerization initiator is used as the photopolymerization initiator. Examples of the photoradical polymerization initiator include a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, and a coumarin compound, and an oxime compound, an α-hydroxyketone compound, an α-aminoketone compound, or an acylphosphine compound is preferable, an oxime compound or an α-aminoketone compound is more preferable, and an oxime compound is still more preferable. As the photopolymerization initiator, compounds described in paragraph Nos. 0099 to 0125 of JP2015-166449A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, and photopolymerization initiators described in JP2019-044030A can also be used, the contents of which are incorporated herein by reference.

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include the compounds described in JP2014-137466A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, the molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, it is preferable that the molar absorption coefficient can be measured using a spectrophotometer (Cary-5 spectrophotometer, manufactured by Varian Medical Systems, Inc.) and ethyl acetate at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in an organic solvent or the like is improved, precipitation is to be difficult over time, and temporal stability of the composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

In a case where the composition according to the embodiment of the present invention contains a photopolymerization initiator, the content of the photopolymerization initiator in the composition according to the embodiment of the present invention is preferably 0.1 mass % or more, more preferably 0.2 mass % or more, and still more preferably 0.5 mass % or more. The upper limit is preferably 10 mass % or less, more preferably 5 mass % or less, and still more preferably 3 mass % or less. In addition, the content of the photopolymerization initiator in the total solid content of the composition according to the embodiment of the present invention is preferably 1 mass % or more, more preferably 2 mass % or more, and still more preferably 5 mass % or more. The upper limit is preferably 30 mass % or less, more preferably 25 mass % or less, and still more preferably 20 mass % or less. In addition, it is preferable to contain 10 to 1000 parts by mass of the photopolymerization initiator with respect to 100 parts by mass of the polymerizable compound. The upper limit is preferably 500 parts by mass or less, more preferably 300 parts by mass or less, and still more preferably 100 parts by mass or less. The lower limit is preferably 20 parts by mass or more, more preferably 40 parts by mass or more, and still more preferably 60 parts by mass or more. The composition according to the embodiment of the present invention may include only one kind of the photopolymerization initiator or two or more kinds thereof. In a case where the composition according to the embodiment of the present invention includes two or more kinds of photopolymerization initiators, it is preferable that the total amount thereof is within the above-described range.

In addition, it is also preferable that the composition according to the embodiment of the present invention does not substantially include the photopolymerization initiator. The case where the composition according to the embodiment of the present invention does not substantially include the photopolymerization initiator means that the content of the photopolymerization initiator in the total solid content of the composition according to the embodiment of the present invention is 0.005 mass % or less, preferably 0.001 mass % or less and more preferably 0 mass %.

<<Resin>>

The composition according to the embodiment of the present invention may further contain a resin. The weight-average molecular weight (Mw) of the resin is preferably 3000 to 2000000. The upper limit is preferably 1000000 or less and more preferably 500000 or less. The lower limit is preferably 4000 or more and more preferably 5000 or more.

Examples of the resin include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, and a silicone resin. These resins may be used singly or as a mixture of two or more kinds thereof. In addition, resins described in paragraph Nos. 0041 to 0060 of JP2017-206689A, resins described in paragraph Nos. 0022 to 0071 of JP2018-010856A, resins described in JP2017-057265A, resins described in JP2017-032685A, resins described in JP2017-075248A, resins described in JP2017-066240A, and resins described in paragraph No. 0016 of JP2018-145339A can also be used.

In the present invention, as the resin, a resin having an acid group can also be preferably used. According to this aspect, developability can be further improved in a case of forming a pattern by a photolithography method. Examples of the acid group include a carboxy group, a phosphoric acid group, a sulfo group, and a phenolic hydroxy group, and a carboxy group is preferable. The resin having an acid group can be used, for example, as an alkali-soluble resin.

The resin having an acid group preferably includes a repeating unit having an acid group in the side chain, and more preferably includes 5 to 70 mol % of repeating units having an acid group in the side chain with respect to the total repeating units of the resin. The upper limit of the content of the repeating unit having an acid group in the side chain is preferably 50 mol % or less and more preferably 30 mol % or less. The lower limit of the content of the repeating unit having an acid group in the side chain is preferably 10 mol % or more and more preferably 20 mol % or more.

The acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 300 mgKOH/g or less, and still more preferably 200 mgKOH/g or less. The weight-average molecular weight (Mw) of the resin having an acid group is preferably 5000 to 100000. In addition, the number-average molecular weight (Mn) of the resin having an acid group is preferably 1000 to 20000.

In a case where the composition according to the embodiment of the present invention contains a resin, the content of the resin in the composition according to the embodiment of the present invention is preferably 0.01 mass % or more, more preferably 0.05 mass % or more, and still more preferably 0.1 mass % or more. The upper limit is preferably 2 mass % or less, more preferably 1 mass % or less, and still more preferably 0.5 mass % or less. In addition, the content of the resin in the total solid content of the composition according to the embodiment of the present invention is preferably 0.2 mass % or more, more preferably 0.7 mass % or more, and still more preferably 1.2 mass % or more. The upper limit is preferably 18 mass % or less, more preferably 12 mass % or less, and still more preferably 5 mass % or less. The composition according to the embodiment of the present invention may include only one kind of the resin or two or more kinds thereof. In a case where the composition according to the embodiment of the present invention includes two or more kinds of resins, it is preferable that the total amount thereof is within the above-described range.

<<Adhesion Improver>>

The composition according to the embodiment of the present invention may further contain an adhesion improver. By containing the adhesion improver, it is possible to form a film having excellent adhesiveness to a support. Suitable examples of the adhesion improver include adhesion improvers described in JP1993-011439A (JP-HOS-011439A), JP1993-341532A (JP-HOS-341532A), JP1994-043638A (JP-H06-043638A), and the like. Specific examples thereof include benzimidazole, benzoxazole, benzthiazole, 2-mercaptobenzimidazole, 2-mercaptobenzoxazole, 2-mercaptobenzthiazole, 3-morpholinomethyl-1-phenyl-triazole-2-thione, 3-morpholinomethyl-5-phenyl-oxadiazole-2-thione, 5-amino-3-morpholinomethyl-thiadiazole-2-thione, 2-mercapto-5-methylthio-thiazole, triazole, tetrazole, benzotriazole, carboxybenzotriazole, amino group-containing benzotriazole, and a silane coupling agent. As the adhesion improver, a silane coupling agent is preferable.

The silane coupling agent is preferably a compound having an alkoxysilyl group as a hydrolyzable group which can be chemically bonded to an inorganic material. In addition, a compound having a group which exhibits an affinity by forming an interaction or bond with the resin is preferable, and examples of such a group include a vinyl group, a styryl group, a (meth)acryloyl group, a mercapto group, an epoxy group, an oxetanyl group, an amino group, a ureido group, a sulfide group, and an isocyanate group, and a (meth)acryloyl group or an epoxy group is preferable.

As the silane coupling agent, a silane compound having at least two kinds of functional groups having different reactivity in one molecule is also preferable, and in particular, a compound having an amino group and an alkoxy group as the functional group is preferable. Examples of such a silane coupling agent include N-β-aminoethyl-γ-aminopropyl-methyldimethoxysilane (KBM-602, manufactured by Shin-Etsu Chemical Co., Ltd.), N-β-aminoethyl-γ-aminopropyl-trimethoxysilane (KBM-603, manufactured by Shin-Etsu Chemical Co., Ltd.), N-β-aminoethyl-γ-aminopropyl-triethoxysilane (KBE-602, manufactured by Shin-Etsu Chemical Co., Ltd.), γ-aminopropyl-trimethoxysilane (KBM-903, manufactured by Shin-Etsu Chemical Co., Ltd.), γ-aminopropyl-triethoxysilane (KBE-903, manufactured by Shin-Etsu Chemical Co., Ltd.), and 3-methacryloxypropyl trimethoxysilane (KBM-503, manufactured by Shin-Etsu Chemical Co., Ltd.). The following compounds can also be used as the silane coupling agent. In the following structural formulae, Et is an ethyl group.

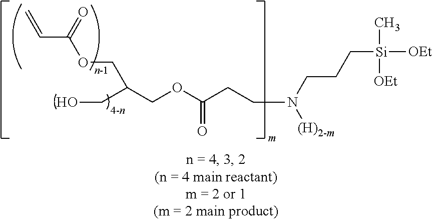

In a case where the composition according to the embodiment of the present invention contains an adhesion improver, the content of the adhesion improver in the total solid content of the composition according to the embodiment of the present invention is preferably 0.001 mass % or more, more preferably 0.01 mass % or more, and particularly preferably 0.1 mass % or more. The upper limit is preferably 20 mass % or less, more preferably 10 mass % or less, and particularly preferably 5 mass % or less. The composition according to the embodiment of the present invention may include only one kind of the adhesion improver or two or more kinds thereof. In a case where the composition according to the embodiment of the present invention includes two or more kinds of adhesion improvers, it is preferable that the total amount thereof is within the above-described range. In addition, it is also preferable that the composition according to the embodiment of the present invention does not substantially include the adhesion improver. The case where the composition according to the embodiment of the present invention does not substantially include the adhesion improver means that the content of the adhesion improver in the total solid content of the composition according to the embodiment of the present invention is 0.0005 mass % or less, preferably 0.0001 mass % or less and more preferably 0 mass %.

<<Other Components>>

In the composition according to the embodiment of the present invention, the content of liberated metal which is not bonded to or coordinated with the silica particles A or the like is preferably 300 ppm or less, more preferably 250 ppm or less, and still more preferably 100 ppm or less, it is particularly preferable to not contain the liberated metal substantially. Examples of the types of the above-described liberated metals include K, Sc, Ti, Mn, Cu, Zn, Fe, Cr, Co, Mg, Al, Sn, Zr, Ga, Ge, Ag, Au, Pt, Cs, Ni, Cd, Pb, and Bi. Examples of a method for reducing liberated metals in the composition include washing with ion exchange water, filtration, ultrafiltration, and purification with an ion exchange resin.

<<Use of Composition>>

The composition according to the embodiment of the present invention can be preferably used as a composition for forming an optically functional layer in an optical instrument such as a display panel, a solar cell, an optical lens, a camera module, and an optical sensor. Examples of the optically functional layer include an antireflection layer, a low refractive index layer, and a waveguide.

In addition, the composition according to the embodiment of the present invention is preferably used as a composition for forming a member or the like adjacent to a colored layer of a color filter having the colored layer (for example, a partition wall such as a grid used to partition adjacent colored layers and a member disposed and used on the upper surface side (light incident side to the colored layer) or the lower surface side (light emitting side from the colored layer) of the colored layer).

The composition according to the embodiment of the present invention can also be preferably used as a composition for forming a partition wall. More specifically, the composition according to the embodiment of the present invention can be preferably used as a composition for forming a partition wall of a structural body which has a support, the partition wall provided on the support, and a colored layer provided in a region partitioned by the partition wall. The type of the colored layer disposed between the partition walls is not particularly limited. Examples thereof include a red colored layer, a blue colored layer, a green colored layer, a yellow colored layer, a magenta colored layer, and a cyan colored layer. The color and disposition of the colored layer can be optionally selected.

In addition, the composition according to the embodiment of the present invention can also be used for manufacturing an optical sensor or the like. Examples of the optical sensor include an image sensor such as a solid-state imaging element.

<Method for Producing Composition>

The composition according to the embodiment of the present invention can be produced by mixing the above-described components. During the production of the composition, it is preferable that the composition is filtered through a filter, for example, in order to remove foreign matters or to reduce defects. As the filter, any filters that have been used in the related art for filtration use and the like may be used without particular limitation. Examples thereof include filters formed of materials including, for example, a fluororesin such as polytetrafluoroethylene (PTFE), a polyamide-based resin such as nylon, and a polyolefin resin (including a polyolefin resin having a high-density or an ultrahigh molecular weight) such as polyethylene and polypropylene (PP). Among these materials, polypropylene (including a high-density polypropylene) and nylon are preferable.

The pore size of the filter is preferably 0.1 to 7 μm, more preferably 0.2 to 2.5 μm, still more preferably 0.2 to 1.5 μm, and even more preferably 0.2 to 0.7 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Toyo Roshi Kaisha., Ltd., Nihon Entegris K.K. (formerly Nippon Microlith Co., Ltd.), Kitz Micro Filter Corporation, and the like can be used.

In a case of using a filter, different filters may be combined. In this case, the filtration with each of the filters may be performed once or may be performed twice or more times. In addition, filters having different pore sizes may be combined.

<Storage Container>

A storage container of the composition according to the embodiment of the present invention is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or compositions. Examples of such a container include the containers described in JP2015-123351A.

In addition, it is also preferable that the interior wall of the storage container is made of glass or stainless steel. According to this aspect, it is possible to prevent metal elution from the interior wall of the container, improve storage stability of the composition, and suppress alteration of the components in the composition.

<Film>

Next, the film according to an embodiment of the present invention is formed of the above-described composition according to the embodiment of the present invention.

The refractive index of the film according to the embodiment of the present invention with light having a wavelength of 633 nm is preferably 1.400 or less, more preferably 1.350 or less, still more preferably 1.300 or less, and even more preferably 1.270 or less. The above-described value of the refractive index is a value at a measurement temperature of 25° C.

It is preferable that the film according to the embodiment of the present invention has sufficient hardness. In addition, the Young's modulus of the film is preferably 2 or more, more preferably 3 or more, and particularly preferably 4 or more. The upper limit value is preferably 10 or less.

The thickness of the film according to the embodiment of the present invention can be appropriately selected depending on the intended use. For example, the thickness of the film is preferably 5 μm or less, more preferably 3 μm or less, and particularly preferably 1.5 μm or less. The lower limit value is not particularly limited, but is preferably 50 nm or more.

The film according to the embodiment of the present invention can be used for an optically functional layer in an optical instrument such as a display panel, a solar cell, an optical lens, a camera module, and an optical sensor. Examples of the optically functional layer include an antireflection layer, a low refractive index layer, and a waveguide.

In addition, the film according to the embodiment of the present invention can be used for a member or the like adjacent to a colored layer of a color filter having the colored layer (for example, a partition wall such as a grid used to partition adjacent colored layers and a member disposed and used on the upper surface side (light incident side to the colored layer) or the lower surface side (light emitting side from the colored layer) of the colored layer). Another layer such as an adhesive layer may be interposed between the above-described member and the colored layer.

<Method for Forming Film>

Next, a method of manufacturing a film will be described. In the method for manufacturing a film, the above-described composition according to the embodiment of the present invention is used. The method for manufacturing a film preferably includes a step of applying the above-described composition to a support to form a composition layer.

Examples of a method for applying the composition include a dropping method (drop casting); a slit coating method; a spray method; a roll coating method; a spin coating method; a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method.

The application in the spin coating method may be performed by a method in which, in a case of applying the composition to the support, the composition is dropped from a nozzle with the rotation of the support stopped, and then the support is rapidly rotated (static dispense method), or a method in which, in a case of applying the composition to the support, the composition is dropped from a nozzle while rotating the support without stopping the rotation of the support (dynamic dispense method). It is also preferable that the application in the spin coating method is performed by changing the rotation speed stepwise. For example, it is preferable to include a main rotation step of determining the film thickness and a dry rotation step for the purpose of drying. In addition, in a case where the time during the main rotation step is short, such as 10 seconds or less, the rotation speed during the subsequent dry rotation step for drying is preferably 400 rpm to 1200 rpm, and more preferably 600 rpm to 1000 rpm. In addition, from the viewpoint of balancing striation suppression and drying, the time of the main rotation step is preferably 1 second to 20 seconds, more preferably 2 seconds to 15 seconds, and still more preferably 2.5 seconds to 10 seconds. As the time of the main rotation step is shorter within the above-described range, occurrence of striations can be suppressed more effectively. In addition, in a case of the dynamic dispense method, for the purpose of suppressing wavy coating unevenness, it is also preferable to reduce the difference between the rotation speed during the dropping of the composition and the rotation speed during the main rotation step. In addition, in the application in the spin coating method, the rotation speed may be increased during the application, as described in JP1998-142603A (JP-H10-142603A), JP1999-302413A (JP-H11-302413A), and JP2000-157922A. In addition, a spin coating process described in “Process Technique and Chemicals for Latest Color Filter” (Jan. 31, 2006, CMC Publishing Co., Ltd.) can also be suitably used.

The support to which the composition is applied can be appropriately selected depending on the intended use. Examples thereof include a substrate formed of a material such as silicon, non-alkali glass, soda glass, PYREX (registered trademark) glass, or quartz glass. In addition, it is also preferable to use an InGaAs substrate or the like. The InGaAs substrate has excellent sensitivity to light having a wavelength of longer than 1000 nm. Therefore, by forming the respective near-infrared transmitting filter layers on the InGaAs substrate, an optical sensor having excellent sensitivity to light having a wavelength of longer than 1000 nm is likely to be obtained. In addition, a charge coupled device (CCD), a complementary metal-oxide semiconductor (CMOS), a transparent conductive film, or the like may be formed on the support. In addition, a black matrix constituting of a light shielding material such as tungsten may be formed on the support. In addition, a base layer may be provided on the support so as to improve adhesiveness to an upper layer, prevent the diffusion of materials, or planarize the surface of the substrate. In addition, a microlens can also be used as the support. By applying the composition according to the embodiment of the present invention to the surface of the microlens, it is possible to form a microlens unit in which a surface is covered with a film consisting of the composition according to the embodiment of the present invention. This microlens unit can be used by incorporating the microlens unit into an optical sensor such as a solid-state imaging element.

The composition layer formed on the support may be dried (pre-baked). The drying is preferably performed at a temperature of 50° C. to 140° C. for 10 seconds to 300 seconds using a hot plate, an oven, or the like.

After the composition layer is dried, a heating treatment (post-baking) may be further performed. The post-baking temperature is preferably 250° C. or lower, more preferably 240° C. or lower, and still more preferably 230° C. or lower. The lower limit is not particularly limited, but is preferably 50° C. or higher and more preferably 100° C. or higher.

The composition layer which has been dried (in a case of performing the post-baking, after post-baking) may be subjected to an adhesion treatment. Examples of the adhesion treatment include a HMDS treatment. In the treatment, hexamethyldisilazane (HMDS) is used. In a case where HMDS is applied to the composition layer formed using the composition according to the embodiment of the present invention, HMDS reacts with a Si—OH bond present on the surface to form Si—O—Si(CH₃)₃. As a result, the surface of the composition layer can be hydrophobic. By making the surface of the composition layer hydrophobic in this way, in a case where a resist pattern described later is formed on the composition layer, the infiltration of a developer into the composition layer can be prevented while improving the adhesiveness of the resist pattern.

The method of manufacturing a film may further include a step of forming a pattern. Examples of the step of forming a pattern include a pattern forming method by a photolithography method and a pattern forming method by an etching method.

(Pattern Formation by Photolithography Method)

First, a case where a pattern is formed by a photolithography method using the composition according to the embodiment of the present invention will be described. Pattern formation by the photolithography method preferably includes a step of forming a composition layer on a support using the composition according to the embodiment of the present invention, a step of exposing the composition layer in a patterned manner, and a step of removing a non-exposed portion of the composition layer by development to form a pattern. A step of baking the composition layer (pre-baking step) and a step of baking the developed pattern (post-baking step) may be provided, as desired.

In the step of forming a composition layer, the composition layer is formed on a support, using the composition according to the embodiment of the present invention. Examples of the support are as described above. Examples of the method for applying the composition include the methods described above. The composition layer formed on the support may be dried (pre-baked). The drying is preferably performed at a temperature of 50° C. to 140° C. for 10 seconds to 300 seconds using a hot plate, an oven, or the like.

Next, the composition layer is exposed in a patterned manner (exposing step). For example, the composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the composition layer is removed by development to form a pattern. The non-exposed portion of the composition layer can be removed by development using a developer. Thus, the composition layer of the non-exposed portion in the exposing step is eluted into the developer, and as a result, only a photocured portion remains. Examples of the developer include an alkali developer and an organic solvent, and an alkali developer is preferable. The temperature of the developer is preferably, for example, 20° C. to 30° C. The development time is preferably 20 to 180 seconds.

As the alkali developer, an aqueous alkaline solution (alkali developer) obtained by diluting an alkali agent with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the aqueous alkaline solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the composition layer after development while rotating the support on which the composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably 250° C. or lower, more preferably 240° C. or lower, and still more preferably 230° C. or lower. The lower limit is not particularly limited, but is preferably 50° C. or higher and more preferably 100° C. or higher. In a case of carrying out the additional exposure treatment, light used for the exposure is preferably light having a wavelength of 400 nm or less. In addition, the additional exposure treatment may be carried out by the method described in KR10-2017-0122130A.

(Pattern Formation by Etching Method)

Next, a case where a pattern is formed by an etching method using the composition according to the embodiment of the present invention will be described. Pattern formation by an etching method preferably includes a step of forming a composition layer on a support using the composition according to the embodiment of the present invention and curing the entire composition layer to form a cured composition layer, a step of forming a photoresist layer on the cured composition layer, a step of exposing the photoresist layer in a patterned manner and then developing the photoresist layer to form a resist pattern, a step of etching the cured composition layer through this resist pattern as a mask, and a step of peeling and removing the resist pattern from the cured composition layer.

A resist used for forming the resist pattern is not particularly limited. For example, a resist including an alkali-soluble phenol resin and naphthoquinone diazide described in pp. 16 to 22 of “Polymer New Material. One Point 3, Microfabrication and Resist, author: Saburo Nonogaki, Published by Kyoritsu Shuppan Co., Ltd. (First Edition, Nov. 15, 1987) can be used. In addition, a resist described in Examples and the like of JP2568883B, JP2761786B, JP2711590B, JP2987526B, JP3133881B, JP3501427B, JP3373072B, JP3361636B, or JP1994-054383A (JP-H06-054383A) can also be used. In addition, as the resist, a so-called chemically amplified resist can also be used. Examples of the chemically amplified resist include a resist described in p. 129 and later of “New Developments of Photo-functional Polymer Materials”, (May 31, 1996, first print, edited by Kunihiro Ichimura, published by CMC) (in particular, a resist including a polyhydroxystyrene resin in which a hydroxy group is protected by an acid-decomposable group that is described in about page 131 or an Environmentally Stable Chemical Amplification Positive (ESCAP) resist which is described in about page 131 is preferable). In addition, a resist described in, for example, Examples and the like of JP2008-268875A, JP2008-249890A, JP2009-244829A, JP2011-013581A, JP2011-232657A, JP2012-003070A, JP2012-003071A, JP3638068B, JP4006492B, JP4000407B, or JP4194249B can also be used.

A method of etching the cured composition layer may be a dry etching or a wet etching. A dry etching is preferable.

The dry etching of the cured composition layer is preferably performed by using a mixed gas of a fluorine-based gas and O₂ as an etching gas. The mixing ratio (fluorine-based gas/O₂) of the fluorine-based gas and O₂ is preferably 4/1 to 1/5, and more preferably 1/2 to 1/4 in terms of flow rate ratio. Examples of the fluorine-based gas include CF₄, C₂F₆, C₃F₈, C₂F₄, C₄F₈, C₄F₆, C₅F₈, and CHF₃, and C₄F₆, C₅F₈, C₄F₈, or CHF₃ is preferable, C₄F₆ or C₅F₈ is more preferable, and C₄F₆ is still more preferable. As the fluorine-based gas, one kind of gas can be selected from the above-described group, and two or more kinds thereof may be included in the mixed gas.

From the viewpoint of maintaining partial pressure control stability of the etching plasma and verticality of the etching shape, the above-described mixed gas may further be mixed with a rare gas such as helium (He), neon (Ne), argon (Ar), krypton (Kr), and xenon (Xe), in addition to the fluorine-based gas and O₂. As other gases which may be mixed, one kind or two or more kinds of gases can be selected from the above-described group. In a case where O₂ is set to be 1, the mixing ratio of the other gases which may be mixed is preferably more than 0 and 25 or less, preferably 10 to 20, and particularly preferably 16 in terms of flow rate ratio.

The internal pressure of a chamber during the dry etching is preferably 0.5 to 6.0 Pa, and more preferably 1 to 5 Pa.

Examples of dry etching conditions include conditions described in paragraph Nos. 0102 to 0108 of WO2015/190374A, and JP2016-014856A, the contents of which are incorporated herein by reference.

An optical sensor or the like can also be manufactured by applying the method for manufacturing a film.

<Structural Body>

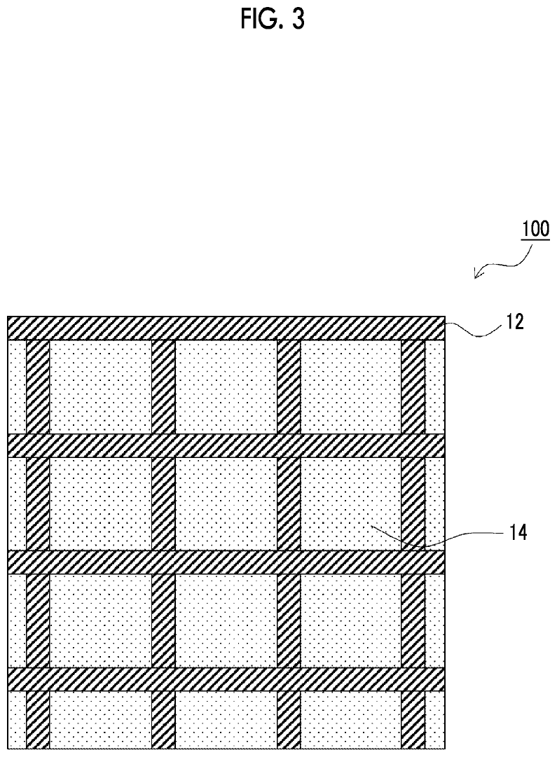

Next, the structural body according to an embodiment of the present invention will be described with reference to drawings. FIG. 2 is a side-sectional view showing an embodiment of the structural body according to the present invention, and FIG. 3 is a plan view of the structural body as viewed from directly above a support. As shown in FIGS. 2 and 3, a structural body 100 according to the embodiment of the present invention includes a support 11, a partition wall 12 provided on the support 11, and a colored layer 14 provided on a region of the support 11 partitioned by the partition wall 12.

The type of the support 11 is not particularly limited. A substrate (silicon wafer, silicon carbide wafer, silicon nitride wafer, sapphire wafer, and glass wafer) used in various electronic devices such as a solid-state imaging element can be used. In addition, a substrate for a solid-state imaging element on which a photodiode is formed can also be used. In addition, as necessary, an undercoat layer may be provided on these substrates so as to improve adhesiveness to an upper layer, prevent the diffusion of materials, or planarize the surface.

As shown in FIGS. 2 and 3, the partition wall 12 is formed on the support 11. In this embodiment, as shown in FIG. 3, the partition walls 12 are formed in a lattice form in a plan view seen from directly above the support 11. In this embodiment, the shape of the region partitioned by the partition wall 12 on the support 11 (hereinafter, also referred to as a shape of an opening portion of the partition wall) is a square shape, but the shape of the opening portion of the partition wall is not particularly limited, and may be, for example, a rectangular shape, a circular shape, an elliptical shape, a polygonal shape, or the like.

The partition wall 12 is formed of the above-described composition according to the embodiment of the present invention. A width W1 of the partition wall 12 is preferably 20 to 500 nm. The lower limit is preferably 30 nm or more, more preferably 40 nm or more, and still more preferably 50 nm or more. The upper limit is preferably 300 nm or less, more preferably 200 nm or less, and still more preferably 100 nm or less. In addition, a height H1 of the partition wall 12 is preferably 200 nm or more, more preferably 300 nm or more, and still more preferably 400 nm or more. The upper limit is preferably the thickness of the colored layer 14×200% or less and more preferably the thickness of the colored layer 14×150% or less, and it is still more preferable that the upper limit is substantially the same as the thickness of the colored layer 14. A height-to-width ratio (height/width) of the partition wall 12 is preferably 1 to 100, more preferably 5 to 50, and still more preferably 5 to 30.

The colored layer 14 is formed in the region (opening portion of the partition wall) of the support 11 partitioned by the partition wall 12. The type of the colored layer 14 is not particularly limited. Examples thereof include a red colored layer, a blue colored layer, a green colored layer, a yellow colored layer, a magenta colored layer, and a cyan colored layer. The color and disposition of the colored layer can be optionally selected. Pixels other than the colored layer may be further formed in the region partitioned by the partition wall 12. Examples of the pixel other than the colored layer include a transparent pixel and a pixel of an infrared transmitting filter.

A width L1 of the colored layer 14 can be appropriately selected depending on applications. For example, the width L1 of the colored layer 14 is preferably 500 to 2000 nm, more preferably 500 to 1500 nm, and still more preferably 500 to 1000 nm. A height (thickness) H2 of the colored layer 14 can be appropriately selected depending on applications. For example, the height H2 of the colored layer 14 is preferably 300 to 1000 nm, more preferably 300 to 800 nm, and still more preferably 300 to 600 nm. In addition, the height H2 of the colored layer 14 is preferably 50% to 150% of the height H1 of the partition wall 12, more preferably 70% to 130% of the height H1 of the partition wall 12, and still more preferably 90% to 110% of the height H1 of the partition wall 12.

In the structural body according to the embodiment of the present invention, it is also preferable that a protective layer is provided on the surface of the partition wall 12. By providing the protective layer on the surface of the partition wall 12, adhesiveness between the partition wall 12 and the colored layer 14 can be improved. As a material of the protective layer, various inorganic materials and organic materials can be used. Examples of the organic material include acrylic resin, polystyrene resin, polyimide resin, and organic spin on glass (SOG) resin. In addition, the protective layer can also be formed using a composition including a compound having an ethylenically unsaturated bond-containing group.

The structural body according to the embodiment of the present invention can be preferably used for a color filter, a solid-state imaging element, an image display device, and the like.

<Color Filter>

The color filter according to the embodiment of the present invention has the film according to the embodiment of the present invention. Examples of the color filter include a color filter having a colored layer and having the film according to the embodiment of the present invention as a member adjacent to the colored layer. Examples of the type of the colored layer include a red colored layer, a blue colored layer, a green colored layer, a yellow colored layer, a magenta colored layer, and a cyan colored layer. The color filter preferably includes two or more colored layers. Examples of the colored layer include an aspect of including a red colored layer, a blue colored layer, and a green colored layer, and an aspect of including a yellow colored layer, a magenta colored layer, and a cyan colored layer.

Examples of the member adjacent to the colored layer include a partition wall which partitions adjacent colored layers and a member disposed and used on the upper surface side (light incident side to the colored layer) or the lower surface side (light emitting side from the colored layer) of the colored layer.

Examples of one embodiment of the color filter include an aspect in which the color filter has two or more colored layers and has a partition wall consisting of the film according to the embodiment of the present invention between the colored layers. A protective layer may be provided on the surface of the partition wall. By providing the protective layer on the surface of the partition wall, adhesiveness between the partition wall and the colored layers can be improved. Examples of a material of the protective layer include those described in the section of structural body described above.

<Solid-State Imaging Element>

The solid-state imaging element according to an embodiment of the present invention has the film according to the embodiment of the present invention. The configuration of the solid-state imaging element according to the embodiment of the present invention is not particularly limited as long as it includes the film according to the embodiment of the present invention and functions as a solid-state imaging element. For example, the following configuration can be adopted.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter including the film according to the embodiment of the present invention on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. An imaging device including the solid-state imaging element according to the embodiment of the present invention can also be used as a vehicle camera or a surveillance camera, in addition to a digital camera or electronic apparatus (mobile phones or the like) having an imaging function.

<Image Display Device>

The image display device according to an embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Next, the present invention will be described with reference to Examples, but the present invention is not limited thereto. The amount and ratio specified in Examples are based on mass unless otherwise specified.

<Preparation of Composition>

Each component was mixed so as to have composition shown in the tables below, and filtration was performed using DFA4201NIEY (0.45 μm nylon filter) manufactured by Nihon Pall Corporation to obtain a composition. The numerical values of the blending amount shown in the tables below indicate parts by mass.

TABLE 1

| | Silica particle solution | | | | Surfactant | | Solvent | |
|---|---|---|---|---|---|---|---|---|
| | | Blending | | Hydrophobizing | | Blending | | Blending |
| | Type | amount | Shape | treatment agent | Type | amount | Type | amount |
| Example 1 | P1 | 45.0 | Beads | Trimethylmethoxysilane | — | 0.0 | S-1 | 8 |
| | | | | | | | S-2 | 43 |
| | | | | | | | S-3 | 3 |
| | | | | | | | S-4 | 0 |
| | | | | | | | S-5 | 0 |
| | | | | | | | S-6 | 1 |
| Example 2 | P1 | 45.0 | Beads | Trimethylmethoxysilane | — | 0.0 | S-1 | 8 |
| | | | | | | | S-2 | 43 |
| | | | | | | | S-3 | 0 |
| | | | | | | | S-4 | 3 |
| | | | | | | | S-5 | 0 |
| | | | | | | | S-6 | 1 |
| Example 3 | P1 | 45.0 | Beads | Trimethylmethoxysilane | — | 0.0 | S-1 | 8 |
| | | | | | | | S-2 | 43 |
| | | | | | | | S-3 | 0 |
| | | | | | | | S-4 | 0 |
| | | | | | | | S-5 | 3 |
| | | | | | | | S-6 | 1 |
| Example 4 | P1 | 45.0 | Beads | Trimethylmethoxysilane | — | 0.0 | S-1 | 8 |
| | | | | | | | S-2 | 43 |
| | | | | | | | S-3 | 0 |
| | | | | | | | S-4 | 2 |
| | | | | | | | S-5 | 1 |
| | | | | | | | S-6 | 1 |
| Example 5 | P1 | 44.8 | Beads | Trimethylmethoxysilane | F-1 | 0.2 | S-1 | 8 |
| | | | | | | | S-2 | 43 |
| | | | | | | | S-3 | 0 |
| | | | | | | | S-4 | 2 |
| | | | | | | | S-5 | 1 |
| | | | | | | | S-6 | 1 |
| Example 6 | P2 | 44.8 | Beads | Triethylmethoxysilane | F-1 | 0.2 | S-1 | 8 |
| | | | | | | | S-2 | 43 |
| | | | | | | | S-3 | 0 |
| | | | | | | | S-4 | 2 |
| | | | | | | | S-5 | 1 |
| | | | | | | | S-6 | 1 |
| Example 7 | P3 | 44.8 | Beads | Hexamethyldisilazane | F-1 | 0.2 | S-1 | 8 |
| | | | | | | | S-2 | 43 |
| | | | | | | | S-3 | 0 |
| | | | | | | | S-4 | 2 |
| | | | | | | | S-5 | 1 |
| | | | | | | | S-6 | 1 |

TABLE 2

| | Silica particle solution | | | | Surfactant | | Solvent | |
|---|---|---|---|---|---|---|---|---|
| | | Blending | | Hydrophobizing | | Blending | | Blending |
| | Type | amount | Shape | treatment agent | Type | amount | Type | amount |
| Example 8 | P4 | 44.8 | Beads | Tetramethoxysilane | F-1 | 0.2 | S-1 | 8 |
| | | | | | | | S-2 | 43 |
| | | | | | | | S-3 | 0 |
| | | | | | | | S-4 | 2 |
| | | | | | | | S-5 | 1 |
| | | | | | | | S-6 | 1 |
| Example 9 | P5 | 44.8 | Beads | Tetraethoxysilane | F-1 | 0.2 | S-1 | 8 |
| | | | | | | | S-2 | 43 |
| | | | | | | | S-3 | 0 |
| | | | | | | | S-4 | 2 |
| | | | | | | | S-5 | 1 |
| | | | | | | | S-6 | 1 |
| Example 10 | P1 | 40.0 | Beads | Trimethylmethoxysilane | — | 0.0 | S-1 | 8 |
| | | | | | | | S-2 | 44 |
| | | | | | | | S-3 | 4 |
| | | | | | | | S-4 | 2 |
| | | | | | | | S-5 | 1 |
| | | | | | | | S-6 | 1 |
| Example 11 | P1 | 35.0 | Beads | Trimethylmethoxysilane | — | 0.0 | S-1 | 8 |
| | | | | | | | S-2 | 45 |
| | | | | | | | S-3 | 8 |
| | | | | | | | S-4 | 2 |
| | | | | | | | S-5 | 1 |
| | | | | | | | S-6 | 1 |
| Example 12 | P1 | 30.0 | Beads | Trimethylmethoxysilane | — | 0.0 | S-1 | 8 |
| | | | | | | | S-2 | 46 |
| | | | | | | | S-3 | 12 |
| | | | | | | | S-4 | 2 |
| | | | | | | | S-5 | 1 |
| | | | | | | | S-6 | 1 |
| Example 13 | P1 | 50.0 | Beads | Trimethylmethoxysilane | — | 0.0 | S-1 | 8 |
| | | | | | | | S-2 | 38 |
| | | | | | | | S-3 | 0 |
| | | | | | | | S-4 | 2 |
| | | | | | | | S-5 | 1 |
| | | | | | | | S-6 | 1 |
| Example 14 | P1 | 55.0 | Beads | Trimethylmethoxysilane | — | 0.0 | S-1 | 8 |
| | | | | | | | S-2 | 33 |
| | | | | | | | S-3 | 0 |
| | | | | | | | S-4 | 2 |
| | | | | | | | S-5 | 1 |
| | | | | | | | S-6 | 1 |

TABLE 3

| | Silica particle solution | | | | Surfactant | | Solvent | |
|---|---|---|---|---|---|---|---|---|
| | | Blending | | Hydrophobizing | | Blending | | Blending |
| | Type | amount | Shape | treatment agent | Type | amount | Type | amount |
| Example 15 | P1 | 44.4 | Beads | Trimethylmethoxysilane | F-1 | 0.6 | S-1 | 8 |
| | | | | | | | S-2 | 43 |
| | | | | | | | S-3 | 0 |
| | | | | | | | S-4 | 2 |
| | | | | | | | S-5 | 1 |
| | | | | | | | S-6 | 1 |
| Example 16 | P1 | 43.8 | Beads | Trimethylmethoxysilane | F-1 | 1.2 | S-1 | 8 |
| | | | | | | | S-2 | 43 |
| | | | | | | | S-3 | 0 |
| | | | | | | | S-4 | 2 |
| | | | | | | | S-5 | 1 |
| | | | | | | | S-6 | 1 |
| Example 17 | P1 | 43.0 | Beads | Trimethylmethoxysilane | F-1 | 2.0 | S-1 | 8 |
| | | | | | | | S-2 | 43 |
| | | | | | | | S-3 | 0 |
| | | | | | | | S-4 | 2 |
| | | | | | | | S-5 | 1 |
| | | | | | | | S-6 | 1 |
| Comparative | P6 | 45.0 | Hollow | Trimethylmethoxysilane | — | 0.0 | S-1 | 8 |
| example 1 | | | | | | | S-2 | 43 |
| | | | | | | | S-3 | 0 |
| | | | | | | | S-4 | 2 |
| | | | | | | | S-5 | 1 |
| | | | | | | | S-6 | 1 |
| Comparative | P7 | 45.0 | Hollow | — | — | 0.0 | S-1 | 8 |
| example 2 | | | | | | | S-2 | 43 |
| | | | | | | | S-3 | 0 |
| | | | | | | | S-4 | 2 |
| | | | | | | | S-5 | 1 |
| | | | | | | | S-6 | 1 |

The raw materials described in the above tables are as follows.

(Silica Particle Solution)

P1: surface-treated silica particle solution which was prepared by 3.0 g of trimethylmethoxysilane as a hydrophobizing treatment agent was added to 100.0 g of propylene glycol monomethyl ether solution (silica particle concentration: 20 mass %) of silica particles (beaded silica) in which a plurality of spherical silicas having an average particle diameter of 15 nm were connected in a bead shape by metal oxide-containing silica (connecting material), and the mixture was reacted at 20° C. for 6 hours

P2: surface-treated silica particle solution which was prepared by 3.0 g of triethylmethoxysilane as a hydrophobizing treatment agent was added to 100.0 g of propylene glycol monomethyl ether solution (silica particle concentration: 20 mass %) of silica particles (beaded silica) in which a plurality of spherical silicas having an average particle diameter of 15 nm were connected in a bead shape by metal oxide-containing silica (connecting material), and the mixture was reacted at 20° C. for 6 hours

P3: surface-treated silica particle solution which was prepared by 3.0 g of hexamethyldisilazane as a hydrophobizing treatment agent was added to 100.0 g of propylene glycol monomethyl ether solution (silica particle concentration: 20 mass %) of silica particles (beaded silica) in which a plurality of spherical silicas having an average particle diameter of 15 nm were connected in a bead shape by metal oxide-containing silica (connecting material), and the mixture was reacted at 20° C. for 6 hours

P4: surface-treated silica particle solution which was prepared by 3.0 g of tetramethoxysilane as a hydrophobizing treatment agent was added to 100.0 g of propylene glycol monomethyl ether solution (silica particle concentration: 20 mass %) of silica particles (beaded silica) in which a plurality of spherical silicas having an average particle diameter of 15 nm were connected in a bead shape by metal oxide-containing silica (connecting material), and the mixture was reacted at 20° C. for 6 hours

P5: surface-treated silica particle solution which was prepared by 3.0 g of tetraethoxysilane as a hydrophobizing treatment agent was added to 100.0 g of propylene glycol monomethyl ether solution (silica particle concentration: 20 mass %) of silica particles (beaded silica) in which a plurality of spherical silicas having an average particle diameter of 15 nm were connected in a bead shape by metal oxide-containing silica (connecting material), and the mixture was reacted at 20° C. for 6 hours

P6: surface-treated silica particle solution which was prepared by 3.0 g of trimethylmethoxysilane as a hydrophobizing treatment agent was added to 100.0 g of THRULYA 4110 (manufactured by JGC C&C, solution of silica particles (silica particles having a hollow structure) having an average particle diameter of 60 nm; SiO₂ equivalent concentration of solid contents: 20 mass %; this solution of silica particles did not include both silica particles in which a plurality of spherical silicas were connected in a bead shape and silica particles in which a plurality of spherical silicas were connected in a plane), and the mixture was reacted at 20° C. for 6 hours P7: THRULYA 4110 (manufactured by JGC C&C, solution of silica particles (silica particles having a hollow structure) having an average particle diameter of 60 nm; SiO₂ equivalent concentration of solid contents: 20 mass %; this solution of silica particles did not include both silica particles in which a plurality of spherical silica particles were connected in a bead shape and silica particles in which a plurality of spherical silica particles were connected in a plane)

Each of the silica particle solutions P1 to P7 were applied to a silicon wafer having a diameter of 8 inches by a spin coating method so that a film thickness after coating was 0.4 μm. Next, the silicon wafer was heated using a hot plate at 100° C. for 2 minutes, and then heated using a hot plate at 200° C. for 5 minutes to form a film. With regard to the obtained film, a contact angle to water at 25° C. (hereinafter, referred to as water contact angle) was measured using a contact angle meter DM-701 manufactured by Kyowa Interface Science Co., Ltd. The amount of water dropped was 6 μL, and the contact angle was measured 6.5 seconds after the drop. The inside of the wafer was randomly measured at four points, and the contact angle was determined from the average value thereof. The water contact angle of the film formed of the silica particle solution P1 was 61°. The water contact angle of the film formed of the silica particle solution P2 was 63°. The water contact angle of the film formed of the silica particle solution P3 was 61°. The water contact angle of the film formed of the silica particle solution P4 was 42°. The water contact angle of the film formed of the silica particle solution P5 was 47°. The water contact angle of the film formed of the silica particle solution P6 was 60°. The water contact angle of the film formed of the silica particle solution P7 could not be measured due to wet spread.

As the average particle diameter of the spherical silica in the silica particle solutions P1 to P5, the number average of circle-equivalent diameters in a projection image of the spherical portions of 50 spherical silicas measured by a transmission electron microscope (TEM) was calculated and obtained. In addition, in the silica particle solutions P1 to P7, by a method of TEM observation, it was investigated whether or not the silica particle solution included silica particles having a shape in which a plurality of spherical silicas were connected in a bead shape and silica particles having a shape in which a plurality of spherical silicas were connected in a plane.

In addition, in the silica particle solutions P1 to P5, in a case where the average particle diameter of the beaded silica was measured using a dynamic light scattering type particle size distribution measuring device (Microtrac UPA-EX150, manufactured by Nikkiso Co., Ltd.), the average particle diameter was all 20 nm.

(Surfactant)

F-1: compound having the following structure (silicone-based nonionic surfactant, carbinol-modified silicone compound; weight-average molecular weight=3000, kinematic viscosity at 25° C.=45 mm²/s)

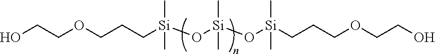

(Solvent)

S-1: 1,4-butanediol diacetate (boiling point: 232° C., viscosity: 3.1 mPa·s, molecular weight: 174)

S-2: propylene glycol monomethyl ether acetate (boiling point: 146° C., viscosity: 1.1 mPa·s, molecular weight: 132)

S-3: propylene glycol monomethyl ether (boiling point: 120° C., viscosity: 1.8 mPa·s, molecular weight: 90)

S-4: methanol (boiling point: 64° C., viscosity: 0.6 mPa·s)

S-5: ethanol (boiling point: 78° C., viscosity: 1.2 mPa·s)

S-6: water (boiling point: 100° C., viscosity: 0.9 mPa·s)

<Temporal Stability>

The composition obtained above was stored at a temperature of 45° C. for 3 days. The kinematic viscosity of the composition before and after storage was measured, and temporal stability of the composition was evaluated using a value of the rate of change in viscosity calculated from the following expression. The kinematic viscosity of the composition was measured with an Ubbelohde viscometer.

Rate of change in viscosity=|1−(Viscosity of composition after storage/Viscosity of composition before storage)|×100

5: rate of change in viscosity was 10% or less.

4: rate of change in viscosity was more than 10% and 15% or less.

3: rate of change in viscosity was more than 15% and 20% or less.

2: rate of change in viscosity was more than 20% and 30% or less.

1: rate of change in viscosity was more than 30%.

<Defects>

The composition obtained above was applied to a silicon wafer having a diameter of 8 inches by a spin coating method so that a film thickness after coating was 0.4 μm. Next, the silicon wafer was heated using a hot plate at 100° C. for 2 minutes, and then heated using a hot plate at 200° C. for 5 minutes to form a film. The obtained film was examined using a defect evaluation device (COMPLUS, manufactured by AMAT), and aggregate-like defects having a size of 2 μm or more were counted to determine the number of defects.

5: number of defects was 10 or less.

4: number of defects was more than 10 and 20 or less.

3: number of defects was more than 20 and 30 or less.

2: number of defects was more than 30 and 50 or less.

1: number of defects was more than 50.

<Refractive Index>

The composition obtained above was applied to a silicon wafer having a diameter of 8 inches by a spin coating method so that a film thickness after coating was 0.4 μm. Next, the silicon wafer was heated using a hot plate at 100° C. for 2 minutes, and then heated using a hot plate at 200° C. for 5 minutes to form a film. The refractive index of the obtained film with light having a wavelength of 633 nm was measured (measurement temperature: 25° C.) using an ellipsometer (VUV-vase, manufactured by J.A. Woollam), and the refractive index was evaluated according to the following standard.

5: refractive index was 1.300 or less.

4: refractive index was more than 1.300 and 1.350 or less.

3: refractive index was more than 1.350 and 1.400 or less.

2: refractive index was more than 1.400 and 1.450 or less.

1: refractive index was more than 1.450.

<Moisture Resistance>

The composition obtained above was applied to a silicon wafer having a diameter of 8 inches by a spin coating method so that a film thickness after coating was 0.4 μm. Next, the silicon wafer was heated using a hot plate at 100° C. for 2 minutes, and then heated using a hot plate at 200° C. for 5 minutes to form a film. The film was subjected to a humidity test for 168 hours under the conditions of a temperature of 130° C. and a humidity of 85% using a highly accelerated life test device (EHS-212, manufactured by ESPEC CORP.). The refractive index of the film before and after the humidity test with light having a wavelength of 633 nm was measured (measurement temperature: 25° C.) using an ellipsometer (VUV-vase, manufactured by J.A. Woollam), the amount of change in refractive index of the film before and after the humidity test was calculated, and the moisture resistance was evaluated according to the following standard.

Amount of change in refractive index=|Refractive index of film before humidity test−Refractive index of film after humidity test|

5: amount of change in refractive index was 0.005 or less.

4: amount of change in refractive index was more than 0.005 and 0.010 or less.

3: amount of change in refractive index was more than 0.010 and 0.020 or less.

2: amount of change in refractive index was more than 0.020 and 0.030 or less.

1: amount of change in refractive index was more than 0.030.

<Evaluation of Moisture Resistance of Colored Layer>

The composition obtained above was applied to a glass wafer having a diameter of 8 inches by a spin coating method, heated at 100° C. for 2 minutes using a hot plate, and further heated at 200° C. for 5 minutes to form a composition layer having a film thickness of 0.4 μm. The composition layer was spin-coated with a positive type photoresist (FFPS-0283, manufactured by FUJIFILM Electronic Materials Co., Ltd.), and heated at 90° C. for 1 minute to form a photoresist layer having a thickness of 1.0 μm. Next, using a KrF scanner exposure machine (FPA6300ES6a, manufactured by Canon Inc.), the laminate was exposed with an exposure amount of 16 J/cm² through a mask, and heated at 100° C. for 1 minute. Thereafter, after developing for 1 minute with a developer (FHD-5, manufactured by FUJIFILM Electronic Materials Co., Ltd.), the laminate was heated at 100° C. for 1 minute to form a mesh-like pattern having a line width of 0.12 μm and a pitch width of 5 μm. Using this pattern as a photo mask, the laminate was patterned by a dry etching method under the conditions described in paragraph Nos. 0129 and 0130 of JP2016-014856A, thereby forming partition walls having a width of 0.1 μm and a height of 0.4 μm in a lattice form at intervals of 5 μm. The size of the opening of the partition wall on the glass wafer (area for one pixel partitioned by the partition wall on the glass wafer) was 4.9 μm in length and 4.9 μm in width.

A coloring composition for a color filter, which will be described later, was applied to the glass wafer in which the partition wall had been formed as described above by a spin coating method so that a film thickness was 0.5 μm, and the laminate was heated at 100° C. for 2 minutes to form a coloring composition layer.

Next, the obtained coloring composition layer was exposed to light (exposure amount: 50 to 1,700 mJ/cm²) by using an i-ray stepper exposure device (FPA-3000 i5+, manufactured by Canon Inc.) through a mask having a pattern of 5.0 μm square.

Next, the exposed cured film was shower-developed at 23° C. for 60 seconds using a 0.3 mass % of aqueous solution of tetramethylammonium hydroxide (TMAH) as a developer. Thereafter, rinsing was performed with pure water by spin shower to obtain a pattern (colored pixel) of the colored layer. In a case where the obtained pattern of the colored layer was observed using a scanning electron microscope (S-4800H, manufactured by Hitachi High-Tech Corporation), it was confirmed that the colored layer was formed without gaps between the partition walls.

The glass wafer in which the colored layer had been formed between the partition walls as described above was subjected to a humidity test for 168 hours under the conditions of a temperature of 130° C. and a humidity of 85% using a highly accelerated life test device (EHS-212, manufactured by ESPEC CORP.). Using a spectrometer system (LVmicro V, manufactured by Lambda Vision Inc.), the transmittance of the colored layer in a wavelength range of 400 to 700 nm before and after the humidity test was measured to determine the maximum value of the amount of change in transmittance, and moisture resistance of the colored layer was evaluated according to the following standard.

The maximum value of the amount of change in transmittance means an amount of change in transmittance of the colored layer in a wavelength which has the largest amount of change in transmittance in a range of 400 to 700 nm before and after the humidity test.

Amount of change in transmittance=|Transmittance of colored layer before humidity test−Transmittance of colored layer after humidity test|

5: maximum value of the amount of change in transmittance was 3% or less.

4: maximum value of the amount of change in transmittance was more than 3% and 5% or less.

3: maximum value of the amount of change in transmittance was more than 5% and 7% or less.

2: maximum value of the amount of change in transmittance was more than 7% and 10% or less.

1: maximum value of the amount of change in transmittance was more than 10%.

The coloring composition used for evaluating the moisture resistance of the colored layer was prepared as follows.

[Preparation of Coloring Composition]

(Dispersion Liquid) 10.6 parts by mass of C. I. Pigment Green 58, 2.7 parts by mass of C. I. Pigment Yellow 185, 1.5 parts by mass of a pigment derivative 1 shown below, 5.2 parts by mass of a dispersant 1 shown below, and 80 parts by mass of propylene glycol monomethyl ether acetate (PGMEA) were mixed with each other, the mixture was mixed and dispersed for 3 hours with a beads mill (zirconia beads: 0.3 mm diameter) and then subjected to a dispersion treatment under a pressure of 2,000 kg/cm³ at a flow rate of 500 g/min using a high-pressure disperser equipped with a pressure reducing mechanism NANO-3000-10 (manufactured by Nippon BEE Chemical Co., Ltd.). The dispersion treatment was repeated 10 times to prepare a dispersion liquid.

Dispersant 1: resin having the following structure (Mw=24,000; a numerical value added to the main chain represents the number of moles, and a numerical value added to the side chain represents the number of repeating units)

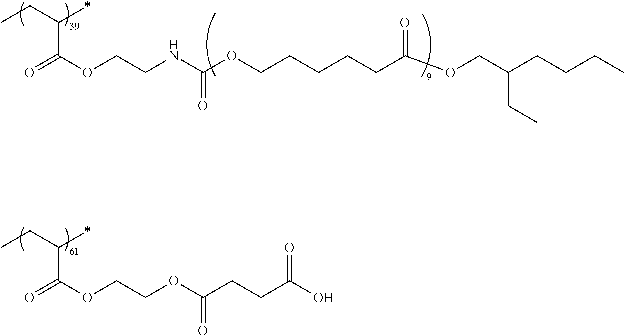

Pigment derivative 1: compound having the following structure (basic pigment derivative)

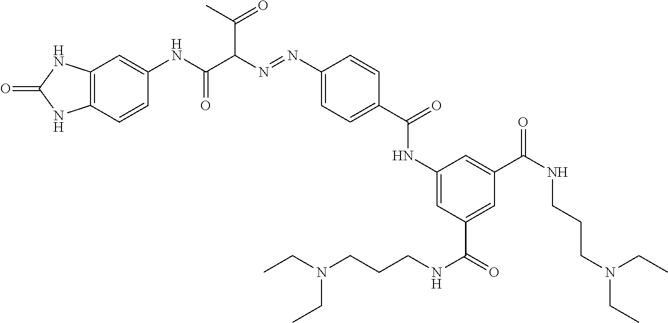 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

(Procedure for Preparing Coloring Composition)

75.0 parts by mass of the dispersion liquid prepared above, 10.0 parts by mass of a resin 1 shown below, 2.0 parts by mass of a polymerizable monomer (KAYARAD DPHA, manufactured by Nippon Kayaku Co., Ltd., dipentaerythritol hexaacrylate), 1.0 part by mass of a photopolymerization initiator (Irgacure OXE01, manufactured by BASF), 0.01 parts by mass of a surfactant 1 shown below, 0.002 parts by mass of a polymerization inhibitor (p-methoxyphenol), and 12.0 parts by mass of propylene glycol monomethyl ether acetate (PGMEA) were mixed with each other to prepare the coloring composition.

Resin 1: resin having the following structure (the numerical value described together with the main chain indicates a number of moles, Mw=11,000)

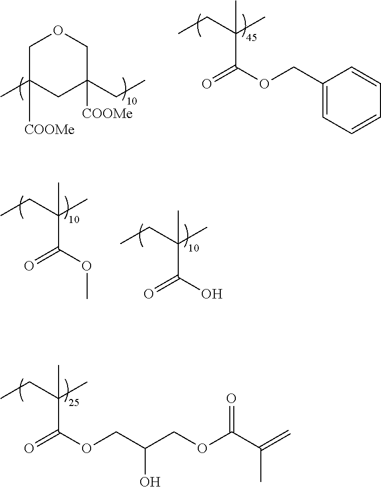

Surfactant 1: compound having the following structure (weight-average molecular weight=14000; numerical value “%” representing the proportion of a repeating unit is mol %)

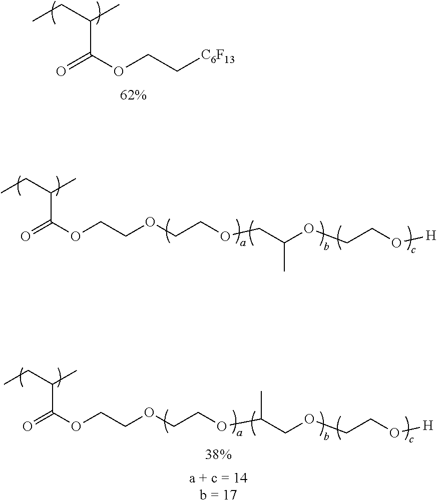

TABLE 4

| | Performance evaluation | | | | |
|---|---|---|---|---|---|
| | | | | | Moisture |
| | Temporal | | Refractive | Moisture | resistance of |
| | stability | Defects | index | resistance | colored layer |
| Example 1 | 4 | 4 | 5 | 5 | 5 |
| Example 2 | 5 | 5 | 5 | 5 | 5 |
| Example 3 | 5 | 4 | 5 | 5 | 5 |
| Example 4 | 5 | 5 | 5 | 5 | 5 |
| Example 5 | 5 | 5 | 5 | 5 | 5 |
| Example 6 | 5 | 4 | 5 | 5 | 5 |
| Example 7 | 5 | 5 | 5 | 5 | 5 |
| Example 8 | 4 | 4 | 5 | 4 | 3 |
| Example 9 | 4 | 3 | 5 | 4 | 3 |
| Example 10 | 5 | 5 | 5 | 5 | 5 |
| Example 11 | 5 | 4 | 5 | 5 | 5 |
| Example 12 | 4 | 4 | 5 | 5 | 5 |
| Example 13 | 5 | 5 | 5 | 5 | 5 |
| Example 14 | 5 | 4 | 5 | 5 | 5 |
| Example 15 | 5 | 5 | 5 | 5 | 5 |
| Example 16 | 5 | 4 | 5 | 5 | 5 |
| Example 17 | 4 | 4 | 5 | 5 | 5 |
| Comparative | 4 | 3 | 3 | 2 | 2 |
| example 1 | | | | | |
| Comparative | 2 | 1 | 3 | 2 | 1 |
| example 2 | | | | | |

As shown in the above table, with the compositions of Examples, it was possible to form a film having a high refractive index and excellent moisture resistance. In addition, by using the compositions of Examples, the moisture resistance of the colored layer could be improved.

In a case where partition walls 40 to 43 of FIG. 1 of JP2017-028241A were produced using the composition of Example 1 to produce an image sensor shown in FIG. 1 of JP2017-028241A, the image sensor was excellent in sensitivity.

### EXPLANATION OF REFERENCES

1: spherical silica
2: connection portion
11: support
12: partition wall
14: colored layer
100: structural body

What is claimed is:

1. A composition comprising:
at least one selected from silica particles in a shape in which a plurality of spherical silicas are connected in a bead shape or silica particles in a shape in which a plurality of spherical silicas are connected in a plane; and
a solvent,
wherein at least a part of hydroxy groups on a surface of the silica particles is treated with a hydrophobizing treatment agent which reacts with the hydroxy group.

2. The composition according to claim 1,
wherein the hydrophobizing treatment agent is an organosilicon compound.

3. The composition according to claim 1,
wherein the hydrophobizing treatment agent is an organosilane compound.

4. The composition according to claim 1,
wherein the hydrophobizing treatment agent is at least one selected from an alkylsilane compound, an alkoxysilane compound, a halogenated silane compound, an aminosilane compound, or a silazane compound.

5. The composition according to claim 1,
wherein the solvent includes an alcohol-based solvent.

6. The composition according to claim 1,
wherein the composition is a composition for forming a member adjacent to a colored layer of a color filter which has the colored layer.

7. The composition according to claim 1,
wherein the composition is a composition for forming a partition wall.

8. The composition according to claim 7,
wherein the composition is a composition for forming a partition wall of a structural body which has a support, the partition wall provided on the support, and a colored layer provided in a region partitioned by the partition wall.

9. A film obtained from the composition according to claim 1.

10. A structural body comprising:
a support;
a partition wall obtained from the composition according to claim 1, which is provided on the support; and
a colored layer provided in a region partitioned by the partition wall.

11. A color filter comprising:
the film according to claim 9.

12. A solid-state imaging element comprising:
the film according to claim 9.

13. An image display device comprising:
the film according to claim 9.
